(19) United States
(12) Patent Application Publication
(10) Pub. No.: US 2026/0354106 A1
(43) Pub. Date: Nov. 5, 2026

(54) METHOD OF MANUFACTURING SEMICONDUCTOR DEVICE

(71) Applicant: SAMSUNG ELECTRONICS CO., LTD., Suwon-si (KR)

(72) Inventors: Hyun YANG, Suwon-si (KR); Jaemok JUNG, Suwon-si (KR); Tae Oh HA, Suwon-si (KR); Jongho PARK, Suwon-si (KR)

(73) Assignee: SAMSUNG ELECTRONICS CO., LTD., Suwon-si (KR)

(21) Appl. No.: 19/642,237

(22) Filed: Apr. 8, 2026

(30) Foreign Application Priority Data
May 2, 2025 (KR) 10-2025-0058082

(51) Int. Cl. H10P 72/70; H10P 72/00

(52) U.S. Cl. CPC H10P 72/7402; H10P 72/0436; H10P 72/0446; H10P 72/7416; H10P 72/7422; H10P 72/744

(57) ABSTRACT

A method of manufacturing a semiconductor device includes attaching a wafer to a tape, and a ring frame to the tape, the ring frame surrounding an outer edge of the wafer with a gap between the wafer and the ring frame, forming a first coating layer in the gap to contact with the wafer, and a second coating layer in the gap to contact with the ring frame, curing the first coating layer and the second coating layer, forming a sacrificial film on the wafer to contact with the first coating layer that has been cured, and removing the sacrificial film.

### CROSS-REFERENCE TO RELATED APPLICATION

This application claims priority from Korean Patent Application No. 10-2025-0058082, filed on May 2, 2025, in the Korean Intellectual Property Office, the contents of which being herein incorporated by reference in its entirety.

### BACKGROUND

Example embodiments relate to a method of manufacturing a semiconductor device.

With a rapid development of the electronics industry and demands of users, electronic devices are being further miniaturized, light-weighted and multi- functionalized, and a semiconductor package used in the electronic devices is also being required to be miniaturized, light-weighted and multi-functionalized. For this miniaturization, a packaging technology for including a semiconductor chip in a single package is being developed. Before a semiconductor chip is packaged, it is advantageous to prevent a wafer from being peeled off of an adhesive tape in a packaging process.

### SUMMARY

It is an aspect to provide a method of manufacturing a semiconductor device which may maintain an adhesive force between a wafer and an adhesive tape.

According to an aspect of one or more embodiments, there is provided a method of manufacturing a semiconductor device, the method comprising attaching a wafer to a tape, and a ring frame to the tape, the ring frame surrounding an outer edge of the wafer with a gap between the wafer and the ring frame; forming a first coating layer in the gap to contact with the wafer, and a second coating layer in the gap to contact with the ring frame; curing the first coating layer and the second coating layer; forming a sacrificial film on the wafer to contact with the first coating layer that has been cured; and removing the sacrificial film.

According to another aspect of one or more embodiments, there is provided a method of manufacturing a semiconductor device, the method comprising attaching a wafer to a tape, and a ring frame to the tape, the ring frame surrounding an outer edge of the wafer with a gap between the wafer and the ring frame; forming a coating layer in the gap to contact an outer surface of the wafer in the gap; curing the coating layer; dicing the wafer into a plurality of dies, the wafer being in contact with the coating layer that has been cured; and picking up a first die among the plurality of dies that is in a central area of the wafer with respect to a plane parallel with a surface of the wafer.

According to yet another aspect of one or more embodiments, there is provided a method of manufacturing a semiconductor device, the method comprising attaching a wafer to a tape, and a ring frame to the tape, the ring frame surrounding an outer edge of the wafer with a gap between the wafer and the ring frame; forming, with a dispenser that discharges a coating material including an epoxy resin, a first coating layer in the gap to cover a portion of an outer surface of the wafer that faces the ring frame and to cover a portion of an upper surface of the tape in the gap, and a second coating layer in the gap to cover a portion of an inner surface of the ring frame that faces the wafer and to cover a portion of the upper surface of the tape; curing the first coating layer and the second coating layer using an UV curing process; forming a photoresist film on the wafer, the portion of the outer surface of which is covered by the first coating layer that has been cured; removing the photoresist film through a stripping process by using a fluid including dimethyl sulfoxide; dicing the wafer from which the photoresist film has been removed into a plurality of dies; and picking up a first die in a central area of the wafer that is not in contact with the first coating layer among the plurality of dies on a plane parallel with a surface of the wafer.

### BRIEF DESCRIPTION OF THE FIGURES

These and/or other aspects will become apparent and more readily appreciated from the following description of example embodiments, taken in conjunction with the accompanying drawings, in which:

FIG. 1 is a flowchart for illustrating a method of manufacturing a semiconductor device according to an example embodiment of the present disclosure;

FIG. 2 is a cross-sectional view for illustrating a wafer and a ring frame being attached to a tape at a gap from each other as a part of a method of manufacturing a semiconductor device;

FIG. 3 is a top plan view for illustrating a first coating layer and a second coating layer being formed at a gap between a wafer and a ring frame, according to an example embodiment of the present disclosure;

FIG. 4 is a cross-sectional view for illustrating a cross section taken along an A-A’ line of FIG. 3;

FIG. 5 is an enlarged view for illustrating by enlarging a portion marked with “CX” in FIG. 4;

FIGS. 6-10 are enlarged views for illustrating a first coating layer and a second coating layer being formed according to various example embodiments of the present disclosure;

FIG. 11 is a cross-sectional view for illustrating curing a first coating layer and a second coating layer as a part of a method of manufacturing a semiconductor device according to an example embodiment of the present disclosure;

FIG. 12 is a cross-sectional view for illustrating curing a first coating layer and a second coating layer according to another example embodiment of the present disclosure;

FIG. 13 is a flowchart for describing an operation S140 illustrated in the flowchart of FIG. 1 in detail, according to an example embodiment of the present disclosure;

FIGS. 14 and 15 are drawings for illustrating a manufacturing order, for describing a part of the method of manufacturing the semiconductor device illustrated in FIG. 13, according to an example embodiment of the present disclosure;

FIG. 16 is a flowchart for describing an operation S140a according to an example embodiment of the present disclosure in detail;

FIGS. 17 and 18 are drawings for illustrating a manufacturing order, for describing a part of the method of manufacturing the semiconductor device illustrated in FIG. 16, according to an example embodiment of the present disclosure;

FIGS. 19-22 are drawings for illustrating a manufacturing order, for describing a part of a method of manufacturing a semiconductor device according to an example embodiment, wherein FIG. 20 is a cross-sectional view for illustrating a cross section taken along a B-B’ line of FIG. 19, and FIG. 22 is a cross-sectional view for illustrating a cross section taken along a C-C’ line of FIG. 21;

FIG. 23 is a flowchart for describing a method of manufacturing a semiconductor device according to an example embodiment of the present disclosure;

FIGS. 24 and 25 are drawings for describing a part of a method of manufacturing a semiconductor device according to an example embodiment of the present disclosure, wherein FIG. 25 is a cross-sectional view for illustrating a cross section taken along a D-D’ line of FIG. 24;

FIGS. 26 and 27 are drawings for describing a part of a method of manufacturing a semiconductor device according to an example embodiment of the present disclosure, wherein FIG. 27 is a cross-sectional view for illustrating a cross section taken along an E-E’ line of FIG. 24; and

FIGS. 28-45 are cross-sectional views for illustrating a manufacturing order, for describing a method of manufacturing a semiconductor package by using a method of manufacturing a semiconductor device according to an example embodiment of the present disclosure.

### DETAILED DESCRIPTION

Before a semiconductor chip is packaged, a wafer is fixed by being attached to an adhesive tape along with a ring frame. Here, it is advantageous that an adhesive force between the adhesive tape and the wafer be maintained in a packaging process.

Hereinafter, example embodiments of the present disclosure will be described in detail with reference to the accompanying drawings. Identical reference numerals will be used for identical components on a drawing, and duplicate descriptions thereof will be omitted for conciseness.

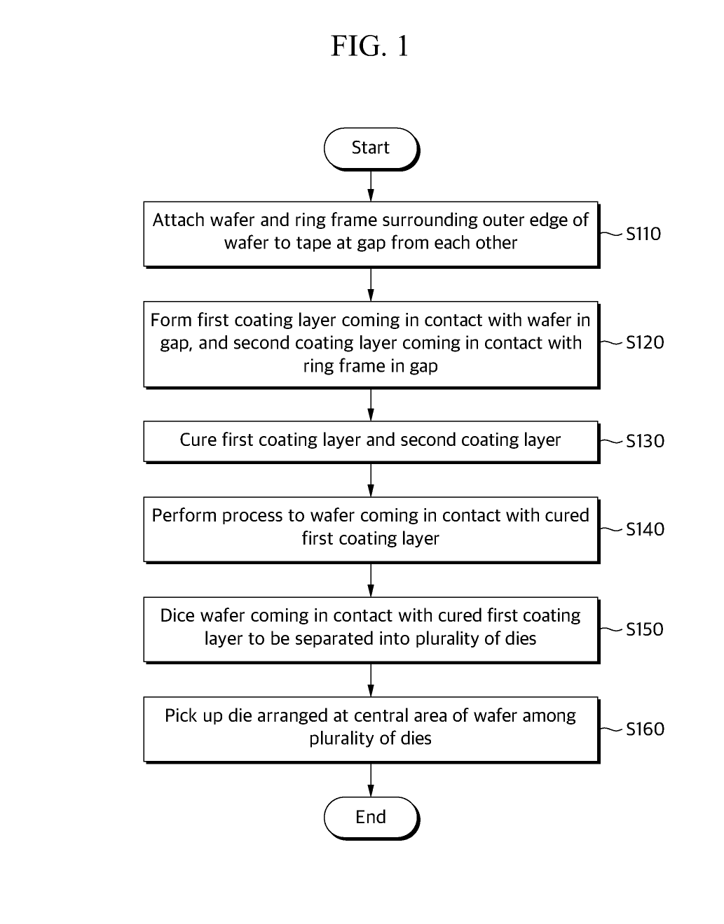

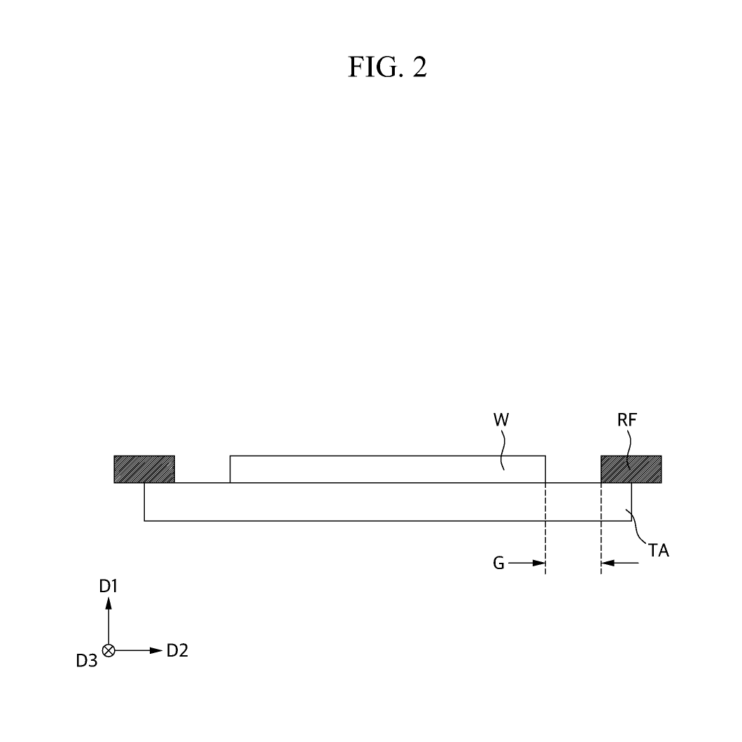

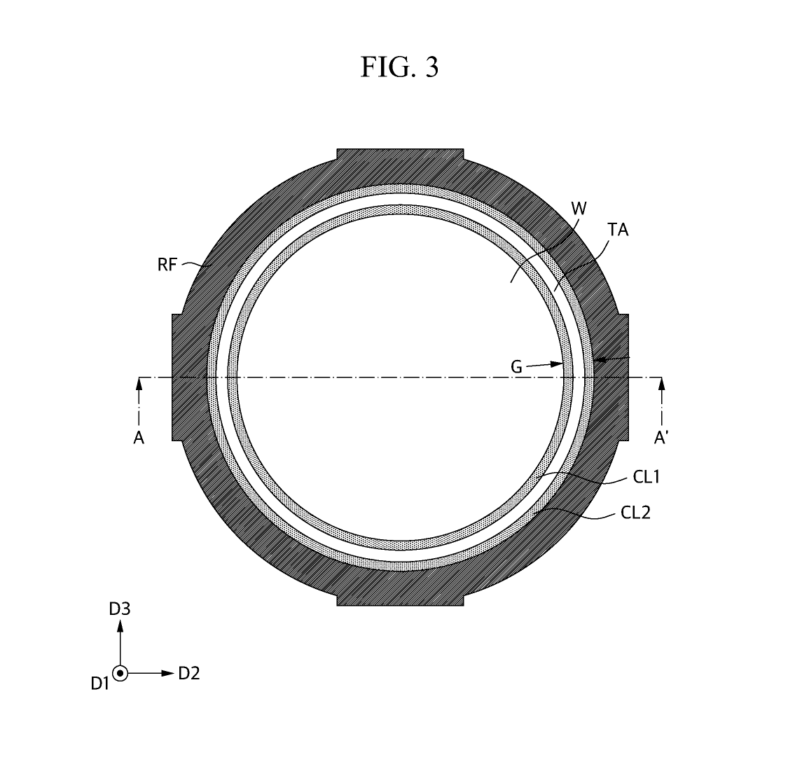

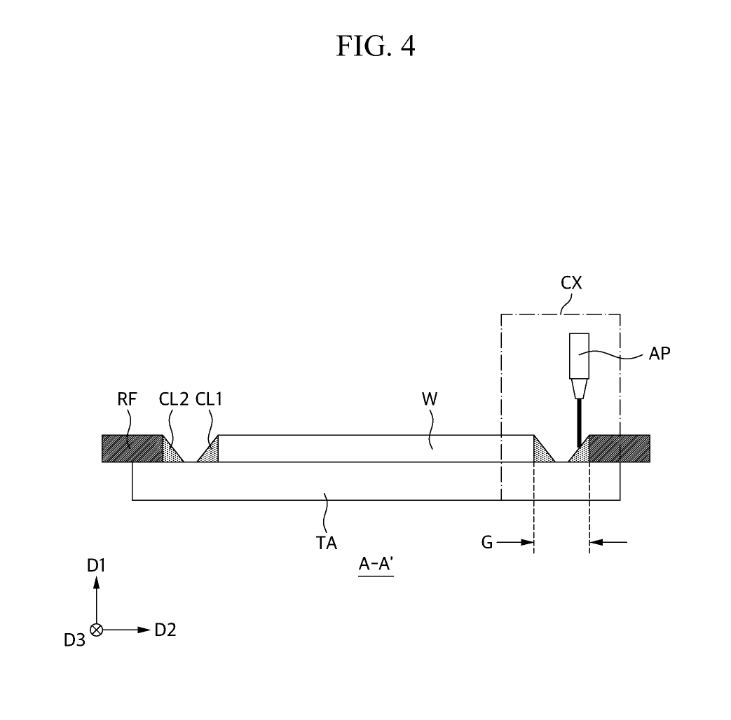

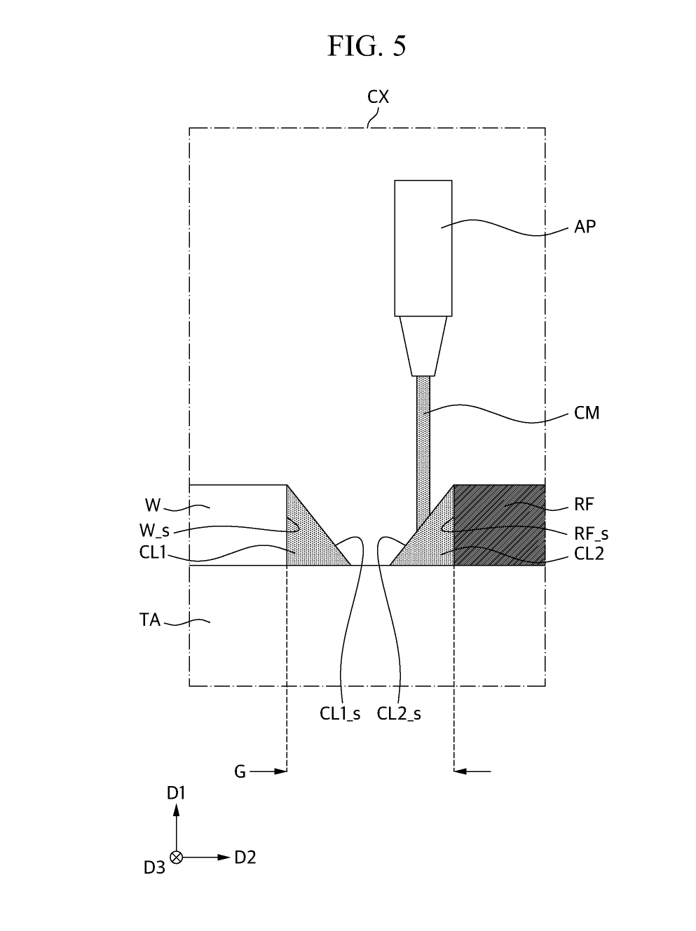

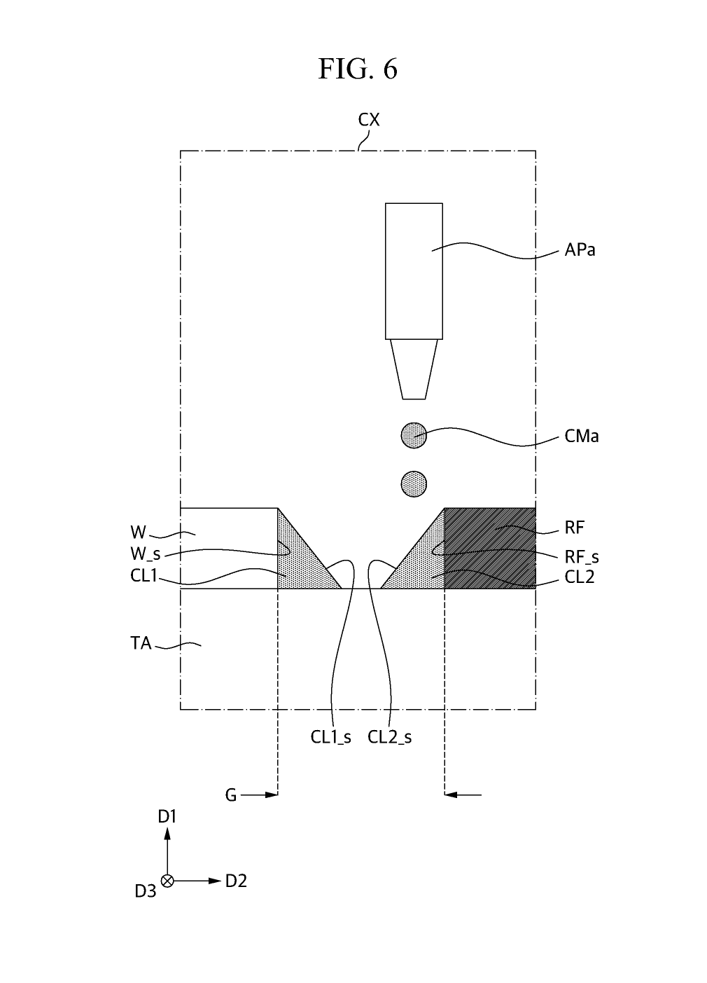

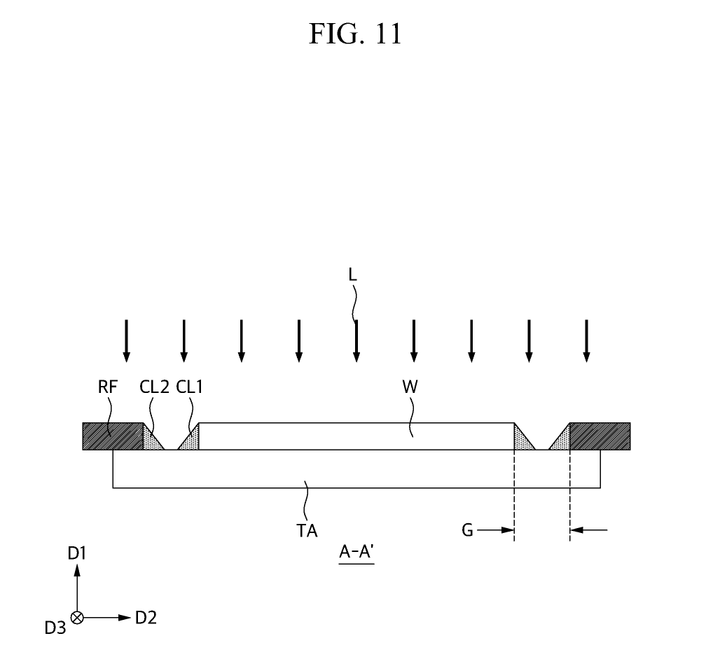

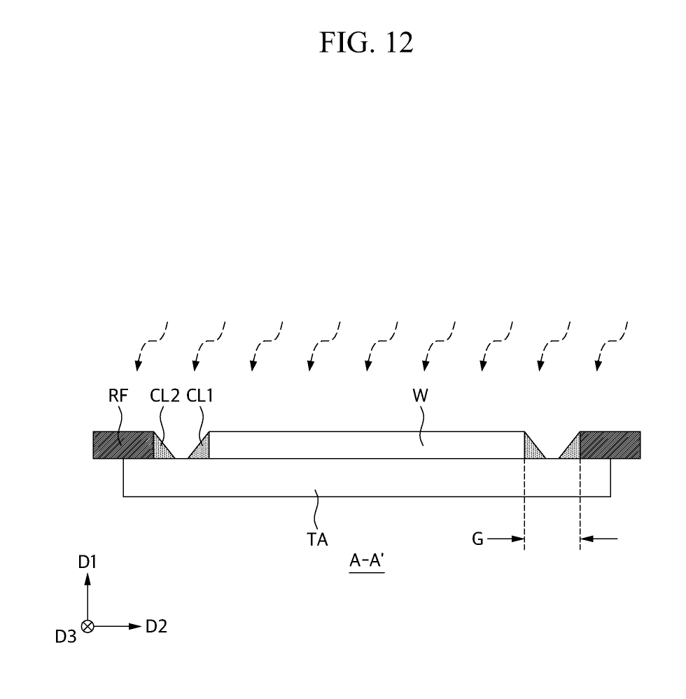

FIG. 1 is a flowchart for illustrating a method of manufacturing a semiconductor device according to an example embodiment of the present disclosure, and FIG. 2 is a part of a method of manufacturing a semiconductor device according to an example embodiment of the present disclosure, and is a cross-sectional view for illustrating a wafer W and a ring frame RF being attached to a tape TA at a gap G from each other. FIG. 3 is a top plan view for illustrating a first coating layer and a second coating layer being formed at a gap between a wafer and a ring frame, and FIG. 4 is a cross-sectional view for illustrating a cross section taken along an A-A’ line of FIG. 3, and FIG. 5 is an enlarged view for illustrating by enlarging a portion marked with “CX” in FIG. 4. FIGS. 6-10 are enlarged views for illustrating a first coating layer and a second coating layer being formed according to various example embodiments of the present disclosure. FIG. 11 is a cross-sectional view for illustrating curing a first coating layer CL1 and a second coating layer CL2 as a part of a method of manufacturing a semiconductor device according to an example embodiment of the present disclosure. FIG. 12 is a cross-sectional view for illustrating curing the first coating layer CL1 and the second coating layer CL2 according to another example embodiment of the present disclosure.

Hereinafter, with reference to FIG. 1, a part of the method of manufacturing the semiconductor device illustrated in FIGS. 2-12 will be described.

Referring to FIG. 2 along with FIG. 1, a method of manufacturing a semiconductor device according to an example embodiment may include operation S110 of attaching the wafer W and the ring frame RF surrounding an outer edge of the wafer W to the tape TA at the gap G from each other.

According to an example embodiment, the tape TA may be an adhesive tape including an adhesive substance. The wafer W having a circular flat surface may be attached to an upper surface of the tape TA, and the ring frame RF may be attached to the upper surface of the tape TA to surround the wafer W at the gap G. A main surface of the wafer W may be attached to the tape TA to face a first direction D1.

In the example embodiment illustrated in FIGS. 1 and 2, the first direction D1 may be a direction of intersecting with the main surface of the wafer W, and a direction in which the tape TA and the wafer W may be arranged in parallel with each other. A second direction D2 may be a direction that intersects with the first direction D1 that is in parallel with the main surface of the wafer W. A third direction D3 may be a direction intersecting with both of the first direction D1 and the second direction D2. A horizontal viewpoint in the present disclosure is a viewpoint of looking down in the first direction D1, and may be a viewpoint on a flat surface being in parallel with the main surface of the wafer W.

According to an example embodiment, the ring frame RF may define a circular space in which the wafer W may be mounted as illustrated in FIG. 3. According to an example embodiment, in a case that the wafer W is not in a circular shape, the ring frame RF may also define a space with a shape other than a circular shape to correspond to a shape of the wafer W.

According to an example embodiment, the wafer W may be a bare wafer including semiconductor materials such as silicon (Si), silicon-germanium (SiGe), gallium arsenide (GaAs), sapphire, silicon carbide (SiC) or the like.

According to an example embodiment, the tape TA may include a base film layer and an adhesive layer stacked on one side of the base film layer. The base film layer provides an overall mechanical supporting force of a tape, and may provide flexibility and tensile strength to respond to an external force or to heat generated during a semiconductor process. The adhesive layer may be evenly attached to a rear surface of the wafer W, and may provide an adhesive force for suppressing a position dislocation or vibration of a wafer during dicing, backgrinding or stripping processes. In an example embodiment, the tape TA may be an ultraviolet (UV) release tape of which an adhesive force is reduced by UV irradiation. In this case, the adhesive layer may include a UV-sensitive substance, and an adhesive characteristic may be reduced when UV rays are irradiated. In an example embodiment, the tape TA may be a thermal release tape of which an adhesive force is reduced in response to heat. The base film layer or the adhesive layer may be used in order for an adhesive characteristic to be attenuated at a temperature or higher. The temperature may be predetermined.

According to an example embodiment, the ring frame RF is a fixing structure for supporting the tape TA to which the wafer W is attached, and may have an edge structure in a closed loop shape around an opening portion. The ring frame RF may include a metal material such as aluminum, stainless steel and the like, high-strength plastic, synthetic resin, or a combination thereof. The ring frame RF may provide sufficient strength with respect to a mechanical load and heat generated during a semiconductor manufacturing process. The ring frame RF may be arranged in a shape of surrounding the outer edge of the wafer W, and may be configured in order for the tape TA, to which the wafer W is attached, to be supported in a level manner while maintaining a uniform tension. Accordingly, deformation, misalignment, vibration and the like which may occur during dicing of the wafer W may be prevented.

Referring to FIGS. 3, 4 and 5 along with FIG. 1, a method of manufacturing a semiconductor device according to an example embodiment may include operation S120 for forming the first coating layer CL1 coming in contact with the wafer W in the gap G, and the second coating layer CL2 coming in contact with the ring frame RF in the gap G.

According to an example embodiment, FIG. 3 is a drawing for viewing the wafer W and the ring frame RF attached to the tape TA from a horizontal viewpoint. FIG. 4 is a cross-sectional view for illustrating the cross section taken along the A-A’ line of FIG. 3. FIG. 5 is an enlarged view for illustrating by enlarging a portion marked with “CX” in FIG. 4.

According to an example embodiment, the gap G in a horizontal viewpoint may be a space extending in a circumferential direction around a center of the wafer W. As best seen in FIG. 5, the gap G may be a space defined between an outer surface W_s of the wafer W and an inner surface RF_s of the ring frame RF in a radial direction at the center of the wafer W. Here, the radial direction may be a direction away from the center of the wafer W along a radius. The first coating layer CL1 and the second coating layer CL2 may be spaced apart from each other in the radial direction from the center of the wafer W.

According to an example embodiment, a dispenser AP may discharge a coating material CM into the gap G to form the first coating layer CL1 and the second coating layer CL2. The first coating layer CL1 may be formed to cover a portion of the outer surface W_s of the wafer W and an upper surface of the tape TA. Here, the outer surface W_s of the wafer W may be a side surface facing the ring frame RF. A portion of the upper surface of the tape TA coming in contact with the first coating layer CL1 may be a surface intersecting with the outer surface W_s of the wafer W.

According to an example embodiment, because the first coating layer CL1 and the second coating layer CL2 are spaced apart from each other in the radial direction from the center of the wafer W in a horizontal viewpoint, the first coating layer CL1 and the second coating layer CL2 may not come in contact with each other.

According to an example embodiment, the second coating layer CL2 may be formed to cover a portion of the inner surface RF_s of the ring frame RF and a portion of the upper surface of the tape TA. Here, the inner surface RF_s of the ring frame RF may be a side surface facing the wafer W. According to an example embodiment, at least a portion of the upper surface of the tape TA may be exposed between the first coating layer CL1 and the second coating layer CL2 in the gap G. The portion of the upper surface of the tape TA coming in contact with the second coating layer CL2 may be a surface intersecting with the inner surface RF_s of the ring frame RF.

According to an example embodiment, the dispenser AP may discharge the coating material CM using a type of fluid which continuously flows. In case that the coating material CM is discharged in a manner of fluid which continuously flows, the first coating layer CL1 and the second coating layer CL2 may be quickly formed.

According to an example embodiment, the first coating layer CL1 may have an inclined side surface CL1_s facing the second coating layer CL2. Because the first coating layer CL1 has the inclined side surface CL1_s, a width in a horizontal direction (a second direction D2 and/or a third direction D3) of the first coating layer CL1 may be narrower from a lower surface of the wafer W towards an upper surface of the wafer W, in other words, in a first direction D1. In some example embodiments, the width of the first coating layer CL1 may not necessarily become gradually narrower in the first direction D1 as illustrated in FIG. 5. Due to limitations in a process, the inclined side surface CL1_s of the first coating layer CL1 may be an uneven concavo-convex surface instead of a smooth flat surface. Even in this case, a width of a surface of the first coating layer CL1 coming in contact with the tape TA may be greater than a width of an upper surface (for instance, a surface having an identical vertical level to the upper surface of the wafer W) of an uppermost end portion of the first coating layer CL1.

According to an example embodiment, in the same manner as the first coating layer CL1, the second coating layer CL2 may have an inclined side surface CL2_s facing the first coating layer CL1. Because the second coating layer CL2 has the inclined side surface CL2_s, a width in a horizontal direction (the second direction D2 and/or the third direction D3) of the second coating layer CL2 may become narrower in the first direction D1. Nevertheless, in the same manner as the first coating layer CL1, the width of the second coating layer CL2 may not necessarily become gradually narrower in the first direction D1. Due to limitations in a process, the inclined side surface CL2_s of the second coating layer CL2 may be an uneven concavo-convex surface instead of a smooth flat surface. Even in this case, a width of a surface of the second coating layer CL2 coming in contact with the tape TA may be greater than a width of an upper surface (for instance, a surface having an identical vertical level to the upper surface of the wafer W) of an uppermost end portion of the second coating layer CL2.

According to an example embodiment, because the wafer W is attached to the tape TA, an interface may be formed between the wafer W and the tape TA. As adhesive force between the wafer W and the tape TA deteriorates, the tape TA may be peeled from the wafer W at an outer edge portion of the wafer W. The first coating layer CL1 may serve to fix the wafer W to the tape TA while surrounding the outer surface W_s of the wafer W. In order to prevent fluid used in a process from infiltrating between the wafer W and the tape TA, the first coating layer CL1 may seal the interface between the wafer W and the tape TA.

According to an example embodiment, in the same manner as the wafer W, because the ring frame RF is attached to the tape TA, an interface may be formed between the ring frame RF and the tape TA. As adhesive force between the ring frame RF and the tape TA deteriorates, the ring frame RF may be peeled from the tape TA at an outer edge portion of the ring frame RF. The second coating layer CL2 may serve to fix the ring frame RF to the tape TA while surrounding the inner surface RF_s of the ring frame RF. In order to prevent fluid used in a process from infiltrating between the ring frame RF and the tape TA, the second coating layer CL2 may seal the interface between the ring frame RF and the tape TA.

According to an example embodiment, the coating material CM discharged by the dispenser AP may be in a fluid state. Therefore, the first coating layer CL1 and the second coating layer CL2 may be in a viscous fluid state. In an example embodiment, the first coating layer CL1 and the second coating layer CL2 may include, for instance, an epoxy resin, a urethane resin, or a combination thereof.

FIGS. 6, 7, 8, 9 and 10 are drawings for respectively describing a method of manufacturing a semiconductor device according to an example embodiment. FIGS. 6, 7, 8, 9 and 10 are enlarged drawings corresponding to the “CX” portion of FIG. 5.

The method of manufacturing the semiconductor device according to the example embodiment illustrated in FIG. 6 is almost identical or similar to the method of manufacturing the semiconductor device illustrated in FIG. 5 except that a method of forming the first coating layer CL1 and the second coating layer CL2 is different. Therefore, descriptions of components which are already described with reference to FIG. 5 will be omitted hereinafter for conciseness.

Referring to FIG. 6, the method of manufacturing the semiconductor device may include forming the first coating layer CL1 coming in contact with the wafer W in the gap G, and the second coating layer CL2 coming in contact with the ring frame RF in the gap G.

According to an example embodiment, an inkjet printing device APa may spray a coating material CMa into the gap G to form the first coating layer CL1 and to form the second coating layer CL2. The first coating layer CL1 and the second coating layer CL2 may be formed by using an inkjet printing method. The inkjet printing device APa may include an ink chamber in which the coating material CMa is filled, and an inkjet head configured to spray the coating material CMa. The inkjet printing device APa may spray the coating material CMa, for instance, in a thermally driven inkjet method or a piezoelectrically driven inkjet method.

According to an example embodiment, the inkjet printing device APa may be configured to spray the coating material CMa into the gap G between the wafer W and the ring frame RF in a form of a droplet. In case that the coating material CMa is sprayed in a form of a droplet, the first coating layer CL1 and the second coating layer CL2 may be finely formed at a uniform thickness in a circumferential direction of the ring frame RF in the gap G.

Because, according to an example embodiment, descriptions with respect to a shape and a function of the first coating layer CL1 and the second coating layer CL2 illustrated in FIG. 6 are similar to descriptions described with reference to FIG. 5, duplicate descriptions will be omitted for conciseness.

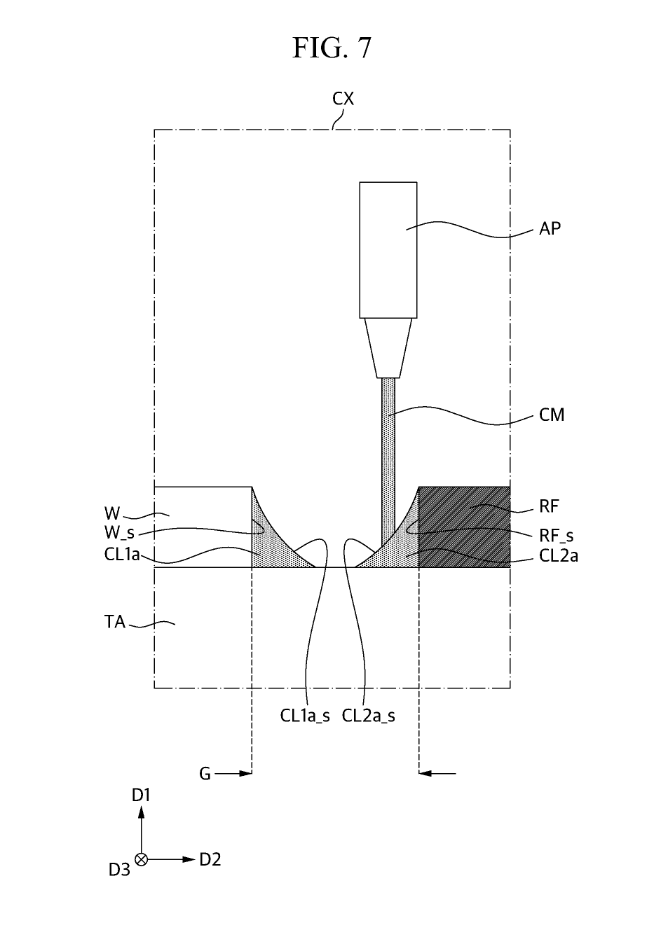

The method of manufacturing the semiconductor device according to an example embodiment illustrated in FIG. 7 is almost identical or similar to the method of manufacturing the semiconductor device illustrated in FIG. 5 except that shapes of a first coating layer CL1a and a second coating layer CL2a are different from each other. Therefore, descriptions to components which are already described with reference to FIG. 5 will be omitted hereinafter for conciseness.

Referring to FIG. 7, the method of manufacturing the semiconductor device may include forming the first coating layer CL1a coming in contact with the wafer W in the gap G, and forming the second coating layer CL2a coming in contact with the ring frame RF in the gap G.

According to an example embodiment, the first coating layer CL1a may have an outer surface CL1a_s facing the second coating layer CL2a. The first coating layer CL1a may have the outer surface CL1a_s which is concavely bent towards the wafer W. As for the first coating layer CL1a, a width in a horizontal direction (the second direction D2 and/or the third direction D3) of the first coating layer CL1a may be nonlinearly reduced from a lower surface of the wafer W towards an upper surface of the wafer W, in other words, in the first direction D1. In an example embodiment, a width of the first coating layer CL1a may become irregularly narrower in the first direction D1. Due to limitations in a process, in some example embodiments, the bent outer surface CL1a_s of the first coating layer CL1a may be an uneven concavo-convex surface instead of having a smooth surface. Even in this case, a width of a surface of the first coating layer CL1a coming in contact with the tape TA may be greater than a width of an upper surface (for instance, a surface having an identical vertical level to the upper surface of the wafer W) of an uppermost end portion of the first coating layer CL1a.

According to an example embodiment, the second coating layer CL2a may have an outer surface CL2a_s facing the first coating layer CL1a. The second coating layer CL2a may have the outer surface CL2a_s which is concavely bent towards the ring frame RF. As for the second coating layer CL2a, a width in a horizontal direction (the second direction D2 and/or the third direction D3) of the second coating layer CL2a may be nonlinearly reduced from a lower surface of the ring frame RF towards an upper surface of the ring frame RF, in other words, in the first direction D1. In an example embodiment, a width of the second coating layer CL2a may become irregularly narrower in the first direction D1. Due to limitations in a process, in some example embodiments, the bent outer surface CL2a_s of the second coating layer CL2a may be an uneven concavo-convex surface instead of having a smooth surface. Even in this case, a width of a surface of the second coating layer CL2a coming in contact with the tape TA may be greater than a width of an upper surface (for instance, a surface having an identical vertical level to the upper surface of the wafer W) of an uppermost end portion of the second coating layer CL2a.

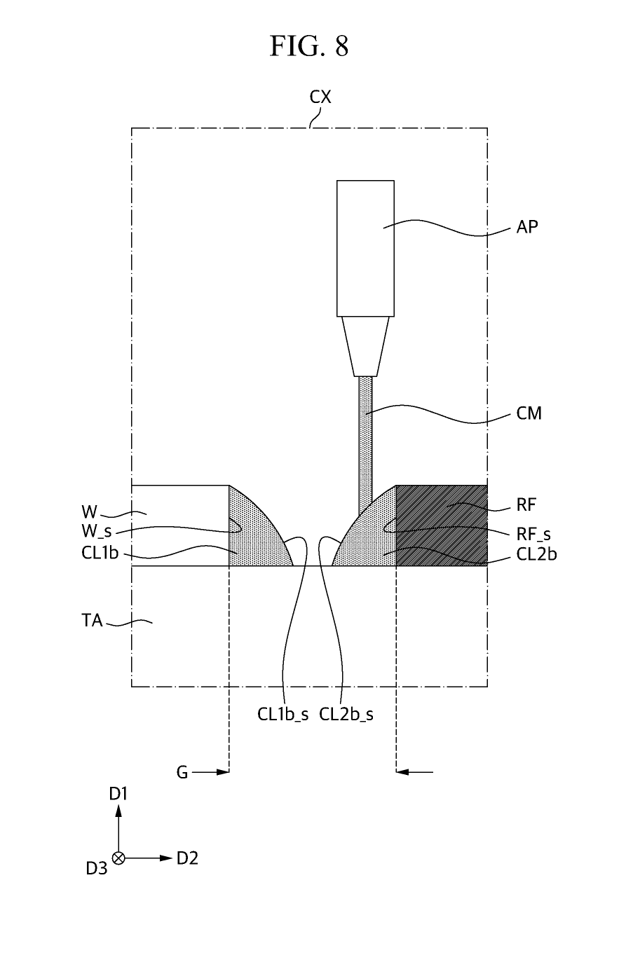

The method of manufacturing the semiconductor device according to an example embodiment illustrated in FIG. 8 is almost identical or similar to the method of manufacturing the semiconductor device illustrated in FIG. 5 except that shapes of the first coating layer CL1a and the second coating layer CL2a are different from each other. Therefore, descriptions of components which are already described with reference to FIG. 5 will be omitted hereinafter for conciseness.

Referring to FIG. 8, the method of manufacturing the semiconductor device may include forming a first coating layer CL1b coming in contact with the wafer W in the gap G, and forming a second coating layer CL2b coming in contact with the ring frame RF in the gap G.

According to an example embodiment, the first coating layer CL1b may have an outer surface CL1b_s facing the second coating layer CL2b. The first coating layer CL1b may have the outer surface CL1b_s which is convexly bent towards the ring frame RF. As for the first coating layer CL1b, a width in a horizontal direction (the second direction D2 and/or the third direction D3) of the first coating layer CL1b may be nonlinearly reduced from a lower surface of the wafer W towards an upper surface of the wafer W, in other words, in the first direction D1. The first coating layer CL1b may have a convex shape by surface tension. The outer surface CL1b_s of the first coating layer CL1b may be, in the same manner as the first coating layer CL1a illustrated in FIG. 7, an uneven concavo-convex surface instead of having a smooth surface. Even in this case, a width of a surface of the first coating layer CL1b coming in contact with the tape TA may be greater than a width of an upper surface (for instance, a surface having an identical vertical level to the upper surface of the wafer W) of an uppermost end portion of the first coating layer CL1b.

According to an example embodiment, the second coating layer CL2b may have an outer surface CL2b_s facing the first coating layer CL1b. The second coating layer CL2b may have the outer surface CL2b_s which is convexly bent towards the wafer W. As for the second coating layer CL2b, a width in a horizontal direction (the second direction D2 and/or the third direction D3) may be nonlinearly reduced from a lower surface of the ring frame RF towards the upper surface of the ring frame RF, in other words, in the first direction D1. The second coating layer CL2b may have a convex shape by surface tension. The outer surface CL2b_s of the second coating layer CL2b may be, in the same manner as the second coating layer CL2a illustrated in FIG. 7, an uneven concavo-convex surface instead of having a smooth surface. Even in this case, a width of a surface of the second coating layer CL2b coming in contact with the tape TA may be greater than a width of an upper surface (for instance, a surface having an identical vertical level to the upper surface of the wafer W) of an uppermost end portion of the second coating layer CL2b.

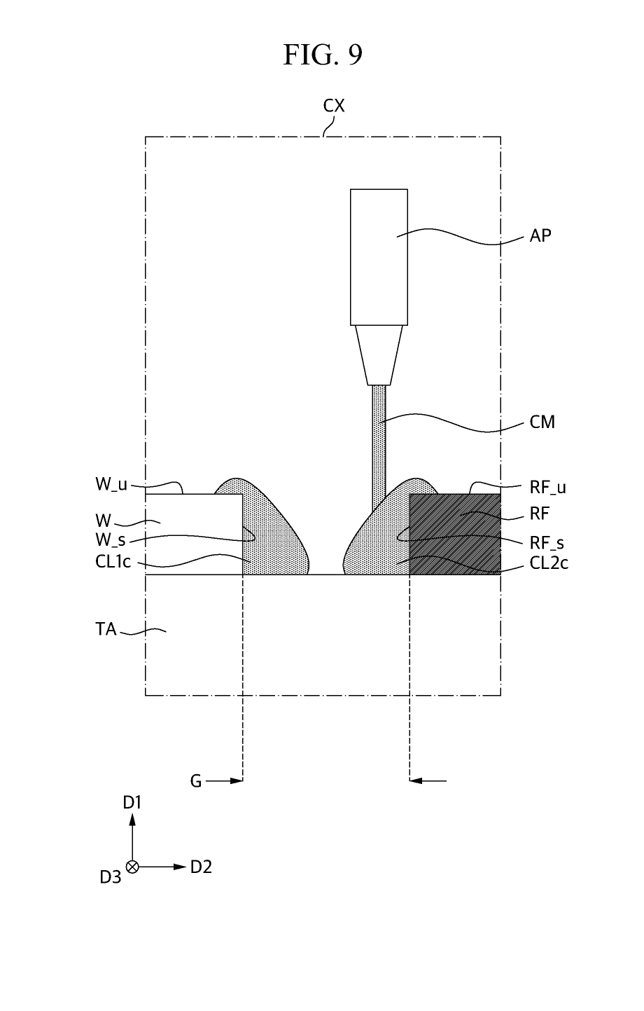

The method of manufacturing the semiconductor device according to an example embodiment illustrated in FIG. 9 is almost identical or similar to the method of manufacturing the semiconductor device illustrated in FIG. 5 except that a first coating layer CL1c covers an upper surface W_u of the wafer W and that a second coating layer CL2c covers an upper surface RF_u of the ring frame RF. Therefore, descriptions of components which are already described with reference to FIG. 5 will be omitted hereinafter for conciseness.

Referring to FIG. 9, the method of manufacturing the semiconductor device according to another example embodiment may include forming the first coating layer CL1c coming in contact with the wafer W in the gap G, and forming the second coating layer CL2c coming in contact with the ring frame RF in the gap G.

According to an example embodiment, the first coating layer CL1c may come in contact with at least a portion of the upper surface W_u of the wafer W, and the second coating layer CL2c may come in contact with at least a portion of the upper surface RF_u of the ring frame RF. The first coating layer CL1c may cover the entire outer surface W_s of the wafer W while covering a portion of the upper surface W_u of the wafer W. The second coating layer CL2c may cover the entire inner surface RF_s of the ring frame RF while covering a portion of the upper surface RF_u of the ring frame RF.

According to an example embodiment, in case that an amount of a coating material discharged by the dispenser AP exceeds a threshold amount, the first coating layer CL1c may be formed to cover a portion of an upper surface of the wafer W. The threshold amount may be predetermined. Likewise, in case that the amount of the coating material discharged by the dispenser AP exceeds the threshold amount, the second coating layer CL2c may be formed to cover a portion of an upper surface of the ring frame RF. The threshold amount may be predetermined. The amount of the coating material of the threshold amount may be an amount of the coating material of a degree sufficient to form the first coating layer CL1 (refer to FIG. 5) and to form the second coating layer CL2 (refer to FIG. 5) illustrated in FIG. 5.

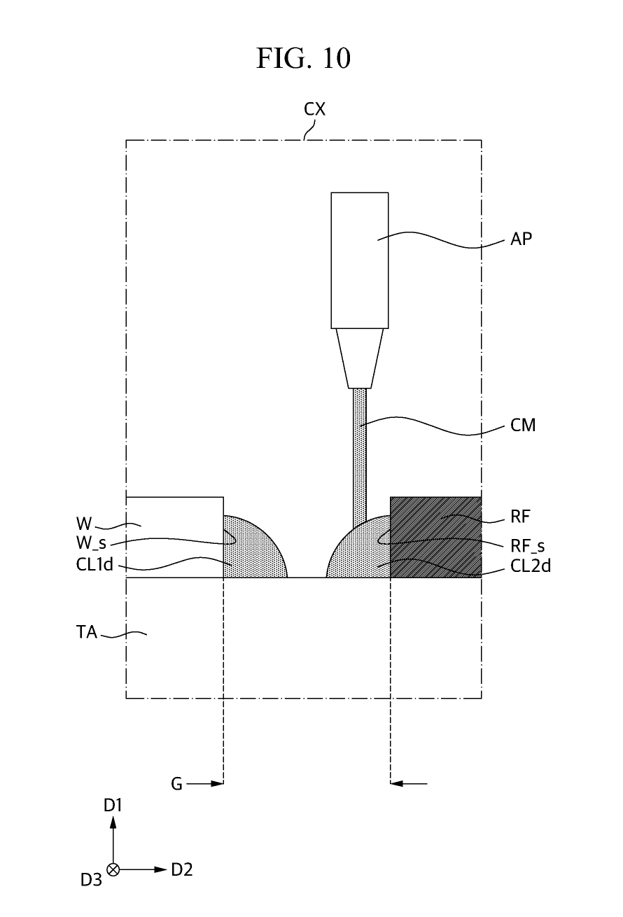

The method of manufacturing the semiconductor device according to an example embodiment illustrated in FIG. 10 is almost identical or similar to the method of manufacturing the semiconductor device illustrated in FIG. 5 except that a first coating layer CL1d does not entirely cover the outer surface W_s of the wafer W and that a second coating layer CL2d does not entirely cover the inner surface RF_s of the ring frame RF. Therefore, descriptions of components which are already described with reference to FIG. 5 will be omitted hereinafter for conciseness.

Referring to FIG. 10, the method of manufacturing the semiconductor device may include forming the first coating layer CL1d coming in contact with the wafer W in the gap G, and forming the second coating layer CL2d coming in contact with the ring frame RF in the gap G.

According to an example embodiment, the wafer W may have the outer surface W_s facing the ring frame RF, and the ring frame RF may have the inner surface RF_s facing the wafer W. The first coating layer CL1d may not cover the entire outer surface W_s of the wafer W, but may cover only a portion of the outer surface W_s. The second coating layer CL2d may not cover the entire inner surface RF_s of the ring frame RF, but may cover only a portion of the inner surface RF_s.

According to an example embodiment, in case that the amount of the coating material discharged by the dispenser AP is less than standard threshold amount, the first coating layer CL1d may be formed to cover only a portion of the outer surface W_s of the wafer W. The threshold amount may be predetermined. Likewise, in case that the amount of the coating material discharged by the dispenser AP is less than the threshold amount, the second coating layer CL2d may be formed to cover only a portion of the inner surface RF_s of the ring frame RF. The threshold amount may be predetermined. The amount of the coating material of the threshold amount may be an amount of the coating material of a degree sufficient to form the first coating layer CL1 and to form the second coating layer CL2 to the top of the wafer W and to the top of the ring frame RF, as illustrated in FIG. 5.

Referring back to FIG. 1 and to FIG. 11 along with FIG. 1, the method of manufacturing the semiconductor device according to an example embodiment may include operation S130 of curing the first coating layer CL1 and the second coating layer CL2.

The first coating layer (e.g., CL1, CL1a, CL1b, CL1c, or CL1d) and the second coating layer (e.g., CL2, CL2a, CL2b, CL2c, or CL2d) illustrated in FIGS. 4, 5, 6, 7, 8, 9 or 10 may be in a viscous fluid state which has not yet undergone a curing process. UV light L may be projected onto the first coating layer CL1 and the second coating layer CL2 to cure the first coating layer CL1 and the second coating layer CL2. When the first coating layer CL1 and the second coating layer CL2 are subjected to the UV light L, the first coating layer CL1 and the second coating layer CL2 may be cured from the viscous fluid state into a complete solid state. In an example embodiment, the UV light L may be an electromagnetic wave of which a wavelength is smaller than about 400 nm.

According to an example embodiment, the first coating layer CL1 and the second coating layer CL2 which are cured by being subjected to the UV light L may include a photocurable composition. For instance, the photocurable composition may include an epoxy resin. The epoxy resin included by the first coating layer CL1 and the second coating layer CL2 may be cured in response to the UV light L. Nevertheless, a material contained in the photocurable composition constituting the first coating layer CL1 and the second coating layer CL2 is not limited to the epoxy resin, and in some example embodiments, the photocurable composition may include a urethane resin, an acrylic compound, and a photoinitiator.

The method of manufacturing the semiconductor device according to an example embodiment illustrated in FIG. 12 is almost identical or similar to the method of manufacturing the semiconductor device illustrated in FIG. 11 except that the first coating layer CL1 and the second coating layer CL2 are cured by a thermal curing processing.

Referring to FIG. 12 along with FIG. 1, the method of manufacturing the semiconductor device according to an example embodiment may include operation S130 of curing the first coating layer CL1 and the second coating layer CL2.

According to an example embodiment, the first coating layer CL1 and the second coating layer CL2 may be cured after heat is applied to the first coating layer CL1 and the second coating layer CL2. When the first coating layer CL1 and the second coating layer CL2 receive an energy by heat of a high temperature, the first coating layer CL1 and the second coating layer CL2 may be cured from the viscous fluid state into the complete solid state. In an example embodiment, the high temperature may be heat equal to or greater than about 100 ℃.

According to an example embodiment, the first coating layer CL1 and the second coating layer CL2 which are cured by receiving an energy by heat of the high temperature may include a thermo-curable composition. For instance, the thermo-curable composition may include a urethane resin. The urethane resin included by the first coating layer CL1 and the second coating layer CL2 may be cured by heat of the high temperature. Nevertheless, a material contained in the thermo-curable composition constituting the first coating layer CL1 and the second coating layer CL2 is not limited to the urethane resin, and in some example embodiments, the thermo-curable composition may include an epoxy resin, a heat curing agent, and a curing accelerator.

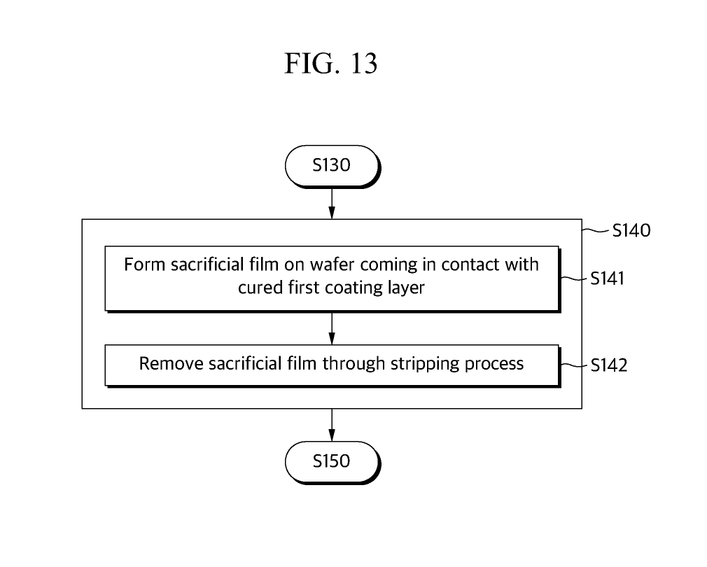

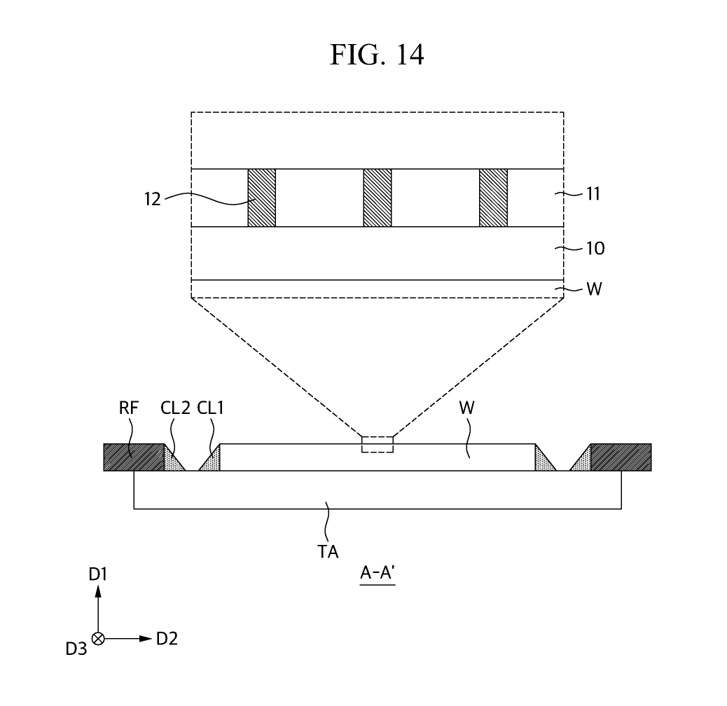

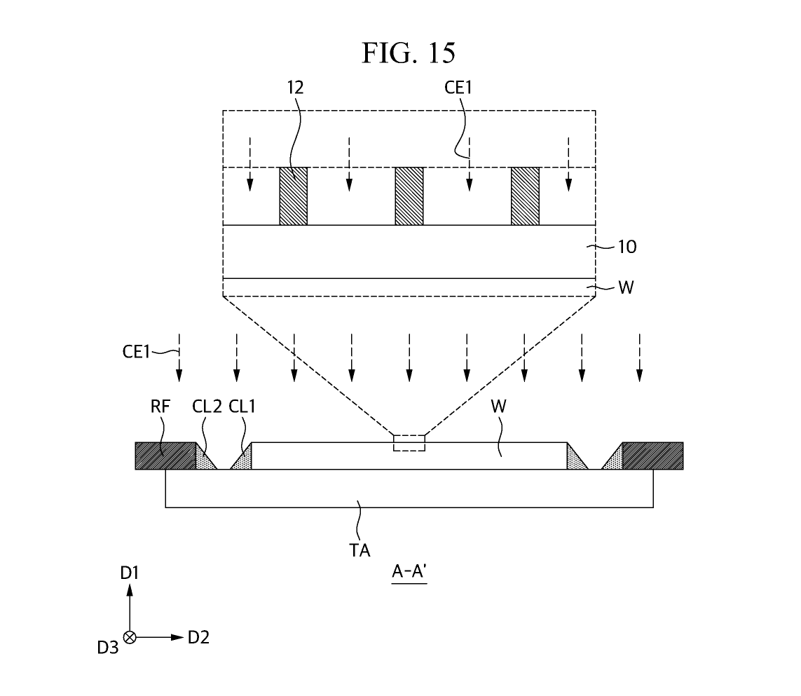

FIG. 13 is a flowchart for describing operation S140 illustrated in FIG. 1 in detail, according to an example embodiment, and FIGS. 14 and 15 are drawings for illustrating a manufacturing order for describing a part of the method of manufacturing the semiconductor device illustrated in FIG. 13.

The method of manufacturing the semiconductor device according to an example embodiment may include operation S140 of performing a process to the wafer W coming in contact with the cured first coating layer CL1. The process may be a stripping process or an etching process depending on an example embodiment. Hereinafter, operation S140 of performing the process to the wafer W will be described in detail.

Referring to FIG. 14 along with FIG. 13, the method of manufacturing the semiconductor device according to an example embodiment may include operation S141 of forming a sacrificial film 11 on the wafer W coming in contact with the cured first coating layer CL1.

According to an example embodiment, a semiconductor structure 10 may be arranged on the wafer W. The semiconductor structure 10 may be a semiconductor chip, and may be a part of a configuration for manufacturing an integrated circuit device depending on an example embodiment. In an example embodiment, the integrated circuit device may include various microelectronic devices, for instance, metal-oxide-semiconductor field effect transistors (MOSFET), such as complementary metal-oxide-semiconductor (CMOS) transistors, system large scale integration (LSI) circuits, image sensors such as CMOS imaging sensors (CIS) and so on, micro-electro-mechanical systems (MEMS), active devices, and/or passive devices.

According to an example embodiment, the sacrificial film 11 and a pattern structure 12 may be arranged on the semiconductor structure 10. The sacrificial film 11 may be located to surround a side surface of the pattern structure 12. The pattern structure 12 may be a conductive pattern constituted with a conductive material depending on an example embodiment. In some example embodiments, the pattern structure 12 may be a pattern constituted with a semiconductor material such as doped polysilicon. In some example embodiments, the pattern structure 12 may be a pattern constituted with an insulating material. The sacrificial film 11 may include, depending on an example embodiment, a spin-on hard mask, an oxide film mask, a nitride film mask, a carbon hard mask, and/or a photoresist material. Nevertheless, a material included by the sacrificial film 11 and the pattern structure 12 is not limited to the materials listed above.

FIG. 14 illustrates a structure in which the structure appears to have an upper surface of the sacrificial film 11 and an upper surface of the pattern structure 12 that are an identical flat surface, but, depending on an example embodiment, the upper surface of the sacrificial film 11 may be located to be higher than the upper surface of the pattern structure 12.

According to an example embodiment, the sacrificial film 11 is firstly formed on the semiconductor structure 10, before holes are formed at the sacrificial film 11 for patterning. A conductive material, a semiconductor material, an insulation material or the like may be filled in the holes formed at the sacrificial film 11 to form the pattern structure 12.

Referring to FIG. 15 along with FIG. 13, the method of manufacturing the semiconductor device according to an example embodiment may include operation S142 of removing the sacrificial film 11 through a stripping process.

According to an example embodiment, the sacrificial film 11 may be removed through a stripping process by applying a stripping solution CE1. The stripping solution CE1 may include sulfuric hydrogen peroxide, tetramethylammonium hydroxide (TMAH), dimethyl sulfoxide (DMSO), isopropyl alcohol (IPA), deionized water (DI) or a combination thereof. A material included in the stripping solution CE1 is not limited to the listed materials. The stripping solution CE1 may be a material in a fluid state.

According to an example embodiment, because the first coating layer CL1 is formed along an outer circumference of the wafer W, the stripping solution CE1 may not infiltrate into an interface between the wafer W and the tape TA. Therefore, an adhesive force between the wafer W and the tape TA may be maintained during the stripping process.

According to an example embodiment, because the second coating layer CL2 is formed along an inner circumference of the ring frame RF, the stripping solution CE1 may not infiltrate into an interface between the ring frame RF and the tape TA. Therefore, an adhesive force between the ring frame RF and the tape TA may be maintained during the stripping process.

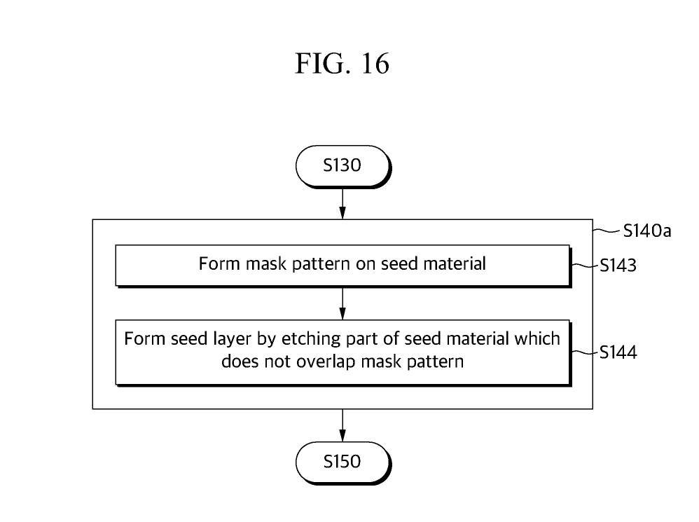

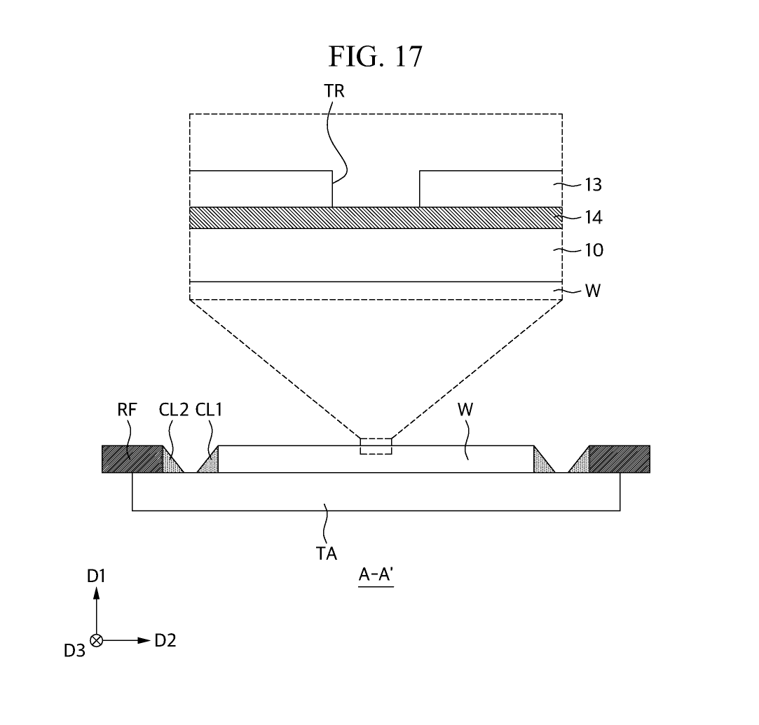

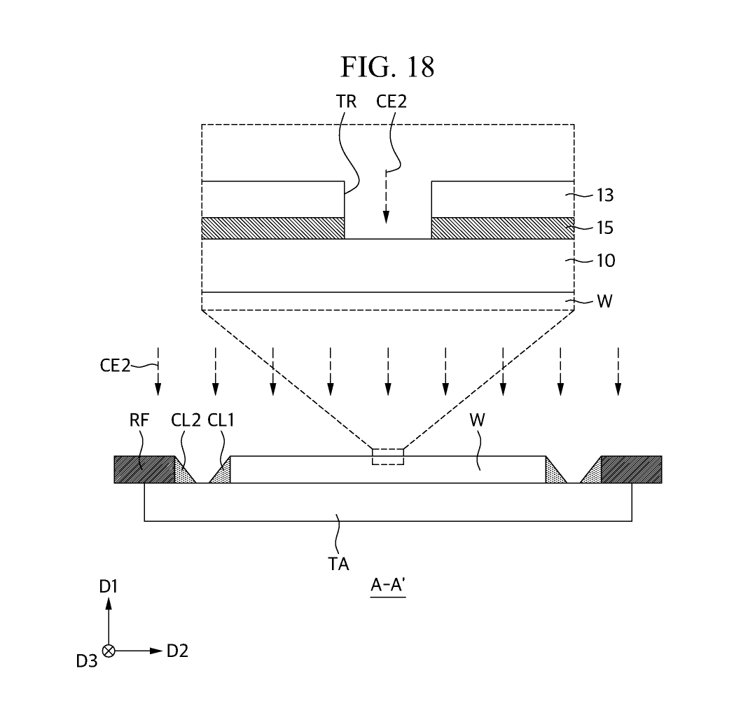

FIG. 16 is a flowchart for describing operation S140a according to an example embodiment of the present disclosure in detail, and FIGS. 17 AND 18 are drawings for illustrating a manufacturing order for describing a part of the method of manufacturing the semiconductor device illustrated in FIG. 16.

Referring to FIG. 17 along with FIG. 16, the method of manufacturing the semiconductor device according to an example embodiment may include operation S143 of forming a mask pattern 13 on a seed material 14.

According to an example embodiment, the semiconductor structure 10 may be arranged on the wafer W. The semiconductor structure 10 may be practically identical to the semiconductor structure 10 illustrated in FIG. 14. Therefore, descriptions which are already described with reference to FIG. 14 will be omitted hereinafter for conciseness.

According to an example embodiment, the seed material 14 and the mask pattern 13 may be formed on the semiconductor structure 10. The mask pattern 13 may be located on the seed material 14. The seed material 14 may be formed on the semiconductor structure 10 by a sputtering process, for instance. The mask pattern 13 may include a material having an etching selection ratio different from an etching selection ratio of the seed material 14. A trench TR may be formed at the mask pattern 13, and a part of the seed material 14 may be exposed through the trench TR.

For instance, the seed material 14 may include copper (Cu), chromium-copper (Cr-Cu), palladium (Pd), platinum (Pt), gold (Au) or a combination thereof. Nevertheless, a material included in the seed material 14 is not limited to the listed materials.

For instance, the mask pattern 13 may include, depending on an example embodiment, a spin-on hard mask, an oxide film mask, a nitride film mask, a metal mask, a carbon hard mask, and/or a photoresist material. Nevertheless, a material included in the mask pattern 13 is not limited to the listed materials.

Referring to FIGS. 17 and18 along with FIG. 16, the method of manufacturing the semiconductor device according to an example embodiment may include operation S144 of forming a seed layer 15 by etching a part of the seed material 14 which does not overlap the mask pattern 13. The part of the seed material 14 which is an etching target may not overlap the mask pattern 13 in the first direction D1.

According to an example embodiment, the seed material 14 which does not overlap the mask pattern 13 in the first direction D1 signifies the part of the seed material 14 which is exposed at the trench TR of the mask pattern 13. The part of the seed material 14 which does not overlap the mask pattern 13 may be removed by an etching process. The etching process may include a dry etching process, a wet etching process or the like. In the etching process, an etching fluid CE2 may be sprayed onto the seed material 14 which is exposed at the trench TR. The part of the seed material 14 exposed to the etching fluid CE2 may be removed. When the part of the seed material 14 is removed, a patterned seed layer 15 may be formed.

According to an example embodiment, in a case of the wet etching process, the etching fluid CE2 may include, for instance, HNO₃, an HCl/H₂O₂ compound, ammonium persulfate (APS), phosphoric acid (H₃PO₄), nitric acid (HNO₃), an acetic acid (CH₃COOH) compound, HF, H₂O₂ or an H₂O₂/NH₄OH compound and the like. Nevertheless, a material included in the liquid chemical solution is not limited to the listed materials.

According to an example embodiment, in a case of the dry etching process, the etching fluid CE2 may include, for instance, Cl₂, BCl₃, SF₆, a gas in which O₂ is mixed with Cl₂, BCl₃, HBr, and CF₄ or the like. Nevertheless, a material included in the etching gas is not limited to the listed materials.

According to an example embodiment, because the first coating layer CL1 is formed along the outer circumference of the wafer W, the etching fluid CE2 may not infiltrate into an interface between the wafer W and the tape TA. Therefore, an adhesive force between the wafer W and the tape TA may be maintained during the etching process.

According to an example embodiment, because the second coating layer CL2 is formed along the inner circumference of the ring frame RF, the etching fluid CE2 may not infiltrate into an interface between the ring frame RF and the tape TA. Therefore, an adhesive force between the ring frame RF and the tape TA may be maintained during the etching process.

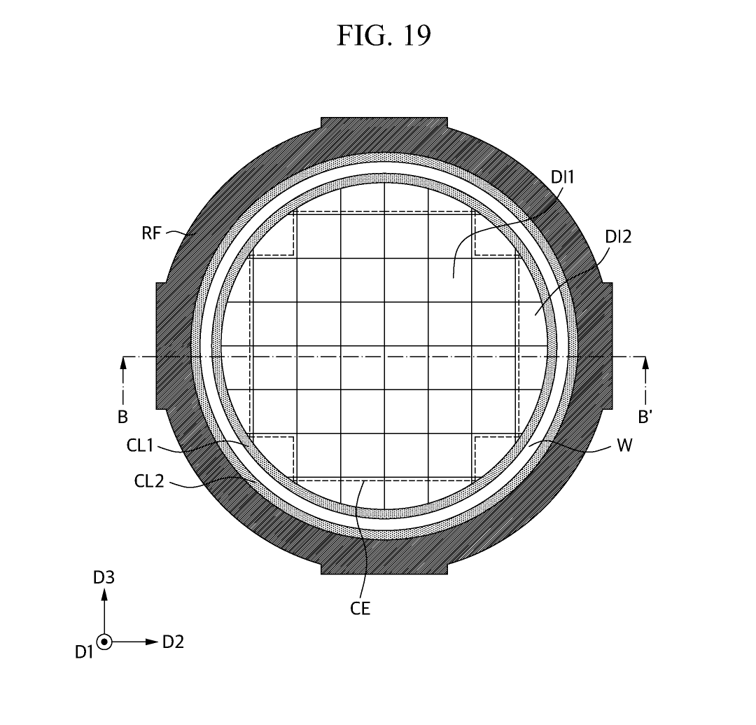

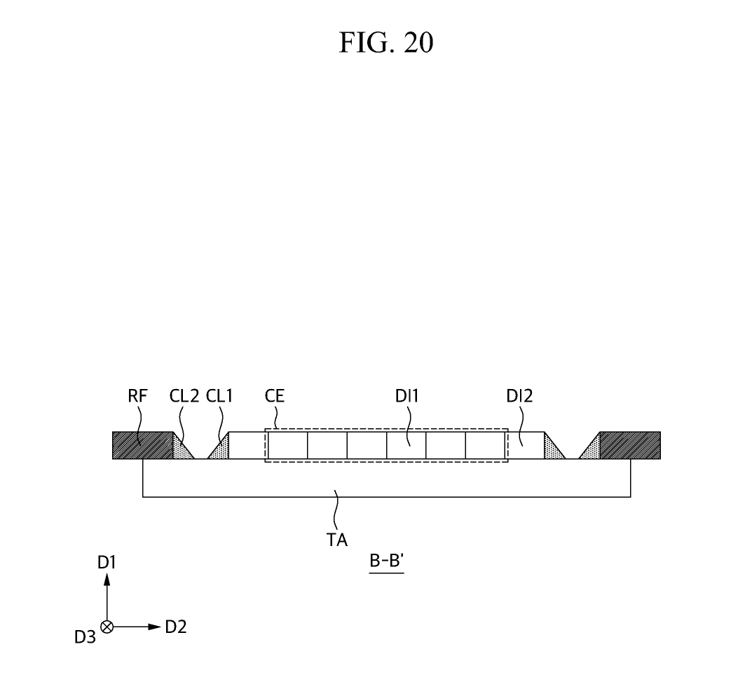

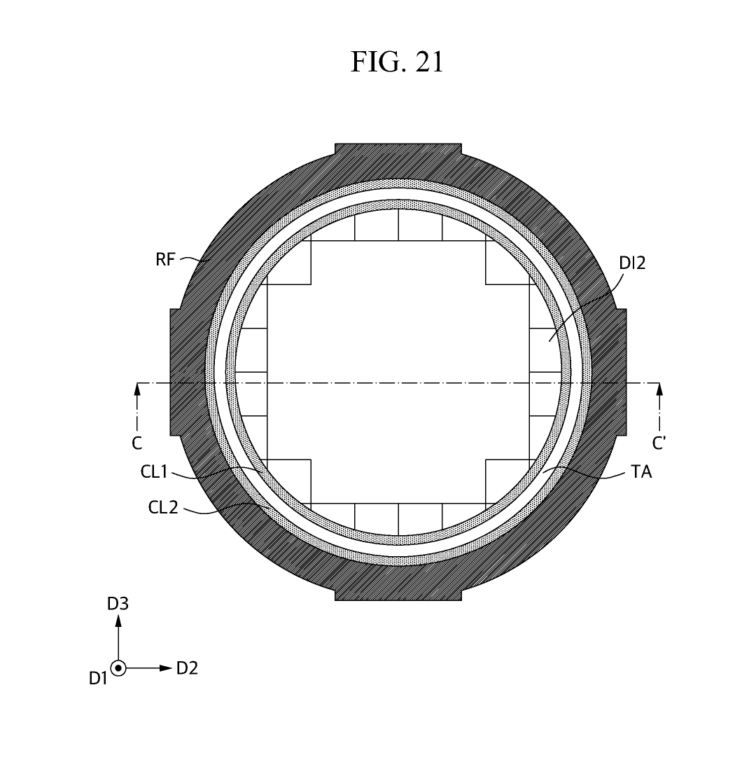

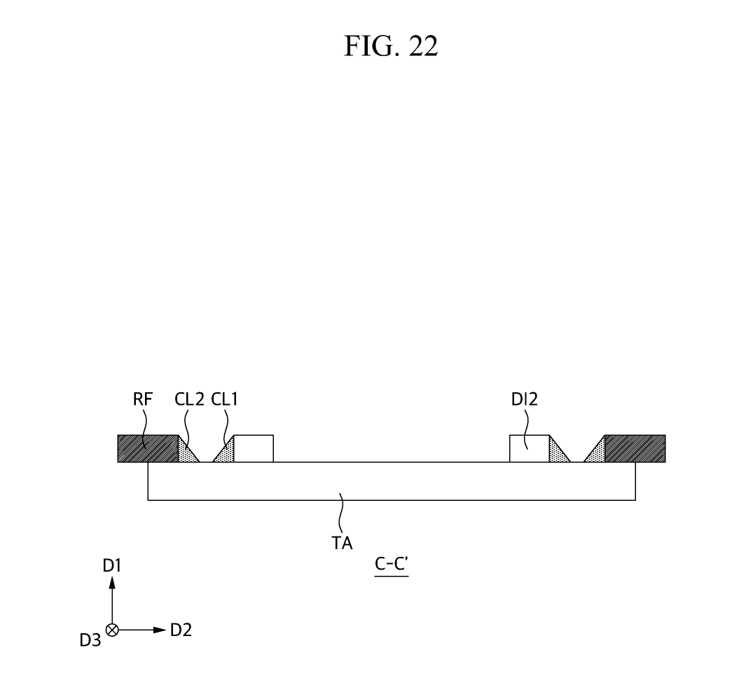

FIGS. 19-22 are drawings for illustrating a manufacturing order for describing a part of the method of manufacturing the semiconductor device according to an example embodiment, wherein FIG. 20 is a cross-sectional view for illustrating a cross section taken along a B-B’ line of FIG. 19, and FIG. 22 is a cross-sectional view for illustrating a cross section taken along a C-C’ line of FIG. 21.

Referring back to FIG. 1 and to FIGS. 19 and 20 along with FIG. 1, the method of manufacturing the semiconductor device according to an example embodiment may include operation S150 of dicing the wafer W coming in contact with the cured first coating layer CL1 to be separated into a plurality of dies (e.g., a first die DI1 and a second die DI2).

According to an example embodiment, the wafer W may be diced to be separated into the plurality of dies (e.g., the first die DI1 and the second die DI2). Dies which do not come in contact with the first coating layer CL1 may be defined as the first die DI1, and dies which come in contact with the first coating layer CL1 may be defined as the second die DI2. The first die DI1 may be defined as dies arranged at a central area CE of the wafer W. The second dies DI2 may be dies located at an outer edge side of the wafer W and dies constituting an edge of the wafer W. The first coating layer CL1 may come in contact with an outer wall of the second dies DI2. The central area CE of the wafer W may be defined as areas excluding an area at which the second dies DI2, which constitute the edge of the wafer W, are arranged.

Referring to FIGS. 21 and 22 along with FIG. 1, the method of manufacturing the semiconductor device according to an example embodiment may include operation S160 of picking up a die arranged at the central area CE (refer to FIGS. 19 and 20) of the wafer W among the plurality of dies (e.g., the first die DI1 and the second die DI2).

According to an example embodiment, a die arranged at the central area CE of the wafer W may be the first die DI1. The first dies DI1 may be picked up to be used in a following semiconductor manufacturing process. For instance, in order for semiconductor packaging, the first dies DI1 may be mounted on another carrier substrate. In some example embodiments, the second dies DI2 which come in contact with the first coating layer CL1 may be discarded. In some example embodiments, the second dies DI2 may be recycled after the first coating layer CL1 is removed. Here, the recycling signifies being utilized for a following semiconductor manufacturing process along with the first dies DI1 which are picked up.

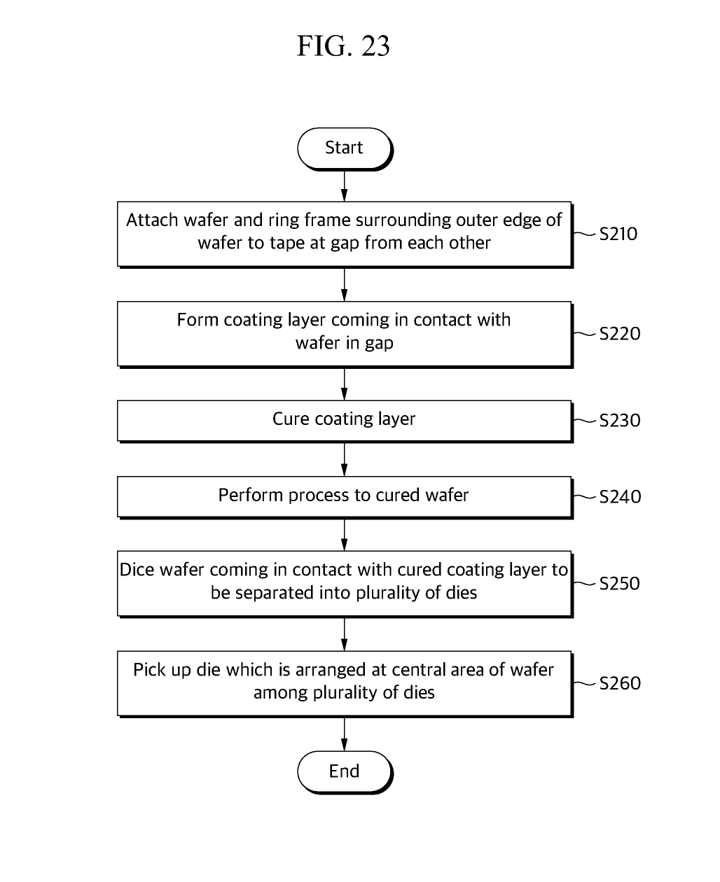

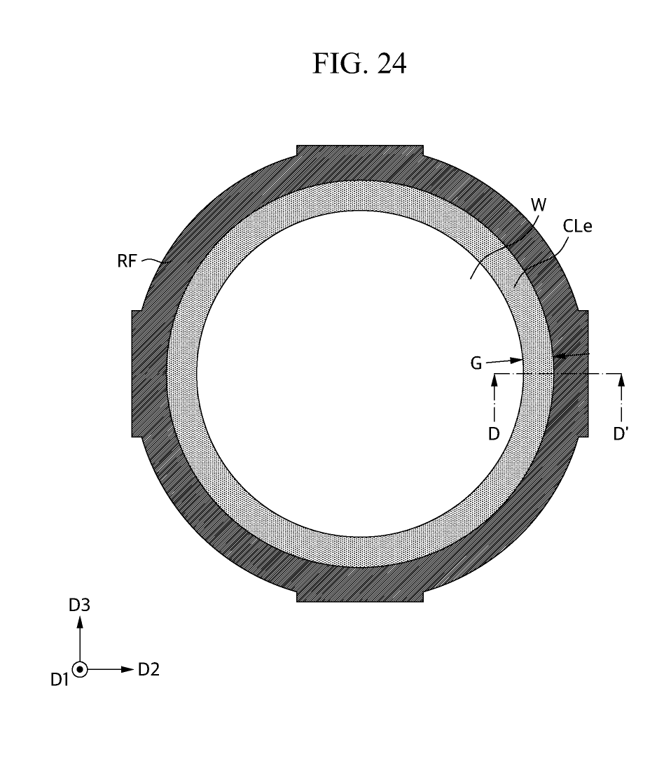

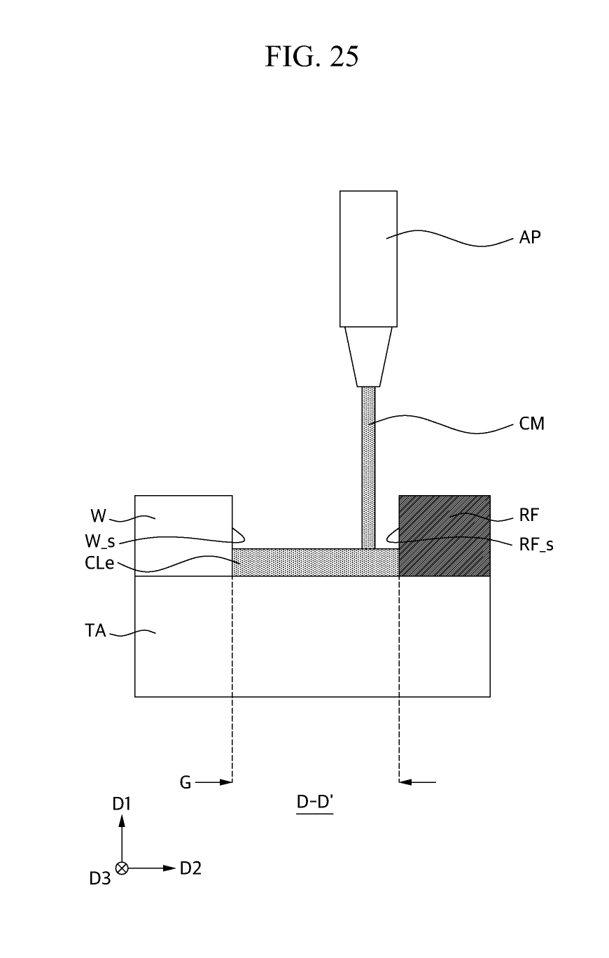

FIG. 23 is a flowchart for describing a method of manufacturing the semiconductor device according to an example embodiment of the present disclosure, and FIGS. 24 and 25 are drawings for describing a part of the method of manufacturing the semiconductor device according to an example embodiment of the present disclosure, wherein FIG. 25 is a cross-sectional view for illustrating a cross section taken along a D-D’ line of FIG. 24.

The method of manufacturing the semiconductor device according to an example embodiment of the present disclosure which is illustrated in FIG. 23 is almost identical or similar to the method of manufacturing the semiconductor device according to an example embodiment which is illustrated in FIG. 1 except that a single coating layer is formed to come in contact with both of the wafer W and the ring frame RF. Therefore, descriptions which are already described with reference to FIG. 1 will be omitted hereinafter for conciseness.

The method of manufacturing the semiconductor device according to an example embodiment may include operation S210 of attaching the wafer W and the ring frame RF, which surrounds an outer edge of the wafer W, to the tape TA at the gap G from each other. Specific descriptions thereof are described with reference to FIG. 2 along with FIG. 1, and thus, duplicate descriptions will be omitted hereinafter for conciseness.

Referring to FIGS. 24 and 25 along with FIG. 23, the method of manufacturing the semiconductor device according to an example embodiment may include operation S220 of forming a coating layer CLe coming in contact with the wafer W in the gap G.

According to an example embodiment, FIG. 24 is a drawing for viewing the wafer W and the ring frame RF attached to the tape TA from a horizontal viewpoint. FIG. 25 is a cross-sectional view for illustrating the cross section taken along the D-D’ line of FIG. 24.

According to an example embodiment, the dispenser AP may discharge the coating material CM into the gap G to form the coating layer CLe. The coating layer CLe may be formed to come in contact with at least a portion of the outer surface W_s of the wafer W and a portion of the upper surface of the tape TA. The outer surface W_s of the wafer W may be a side surface facing the ring frame RF. The coating layer CLe may be formed to come in contact with at least a portion of the inner surface RF_s of the ring frame RF. In a horizontal viewpoint, the coating layer CLe may fill the gap G between the wafer W and the ring frame RF. Because the coating layer CLe is formed on the wafer W, the wafer W may not be exposed by the gap G. In order to prevent an interface between the wafer W and the tape TA and an interface between the ring frame RF and the tape TA from being exposed, in an example embodiment, the coating layer CLe may completely cover the tape TA exposed at the gap G.

According to an example embodiment, the coating layer CLe may have a flat upper surface. Nevertheless, this configuration is merely an example, and the upper surface of the coating layer CLe may have a curve depending on an example embodiment.

The method of manufacturing the semiconductor device according to an example embodiment may include operation S230 of curing the coating layer CLe. Specific descriptions thereof are described with reference to FIGS. 11 and 12, and thus, duplicate descriptions will be omitted hereinafter for conciseness. In some example embodiments, as illustrated in FIG. 11, the coating layer CLe may be cured by the UV light L (refer to FIG. 11) that is projected. In some example embodiments, the coating layer CLe may be cured by a thermal curing processing as illustrated in FIG. 12.

The method of manufacturing the semiconductor device according to an example embodiment may include operation S240 of performing a process to the cured wafer W. Specific descriptions thereof are described with reference to FIGS. 13-18, and thus, duplicate descriptions will be omitted hereinafter for conciseness. In some example embodiments, the process may be the stripping process as illustrated in FIGS. 13-15. In some example embodiments, the process may be an etching process as illustrated in FIGS. 16-18.

The method of manufacturing the semiconductor device according to an example embodiment may include operation S250 of dicing the wafer W coming in contact with the cured coating layer CLe to be separated into a plurality of dies. Specific descriptions thereof are described with reference to FIGS. 19 and 20, and thus, duplicate descriptions will be omitted hereinafter for conciseness.

The method of manufacturing the semiconductor device according to an example embodiment may include operation S260 of picking up a die arranged at the central area CE of the wafer W among the plurality of dies. Specific descriptions thereof are described with reference to FIGS. 21 and 22, and thus, duplicate descriptions will be omitted hereinafter for conciseness.

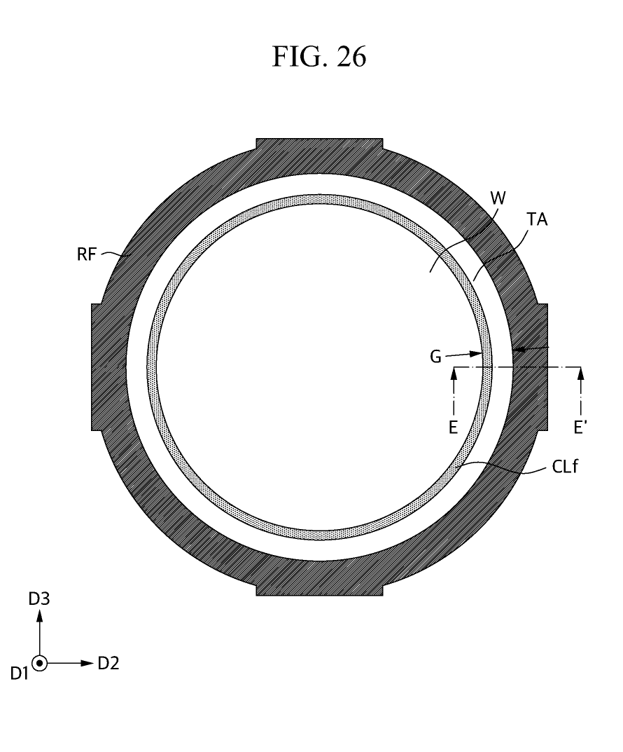

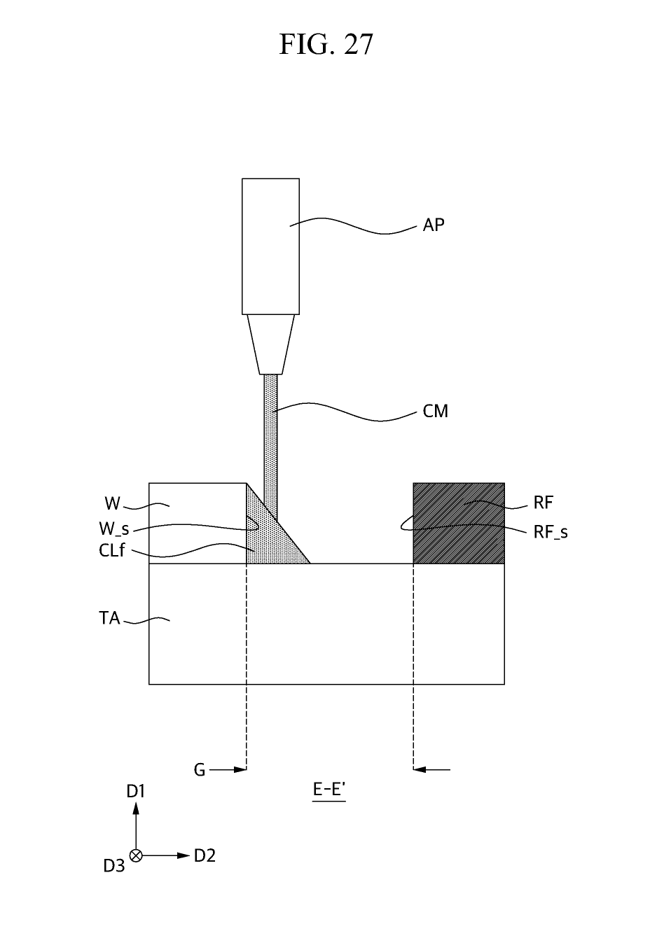

FIGS. 26 and 27 are drawings for describing a part of the method of manufacturing the semiconductor device according to an example embodiment of the present disclosure, wherein FIG. 27 is a cross-sectional view for illustrating a cross section taken along an E-E’ line of FIG. 24.

A part of the method of manufacturing the semiconductor device according to the example embodiment which is illustrated in FIGS. 26 and 27 may be an operation corresponding to operation S220 for forming the coating layer CLe illustrated in FIGS. 24 and 25.

According to an example embodiment, FIG. 26 is a drawing for viewing the wafer W and the ring frame RF attached to the tape TA from a horizontal viewpoint. FIG. 27 is a cross-sectional view for illustrating the cross section taken along the E-E’ line of FIG. 26.

According to an example embodiment, the dispenser AP may discharge the coating material CM into the gap G to form a coating layer CLf. The coating layer CLf may be formed to come in contact with at least a portion of the outer surface W_s of the wafer W and a portion of an upper surface of the tape TA. Here, the outer surface W_s of the wafer W may be a side surface facing the ring frame RF. The coating layer CLf may not come in contact with the inner surface RF_s of the ring frame RF.

According to an example embodiment, an inner surface of the ring frame RF may be exposed to the outside. The inner surface of the ring frame RF may face the coating layer CLf in the gap G.

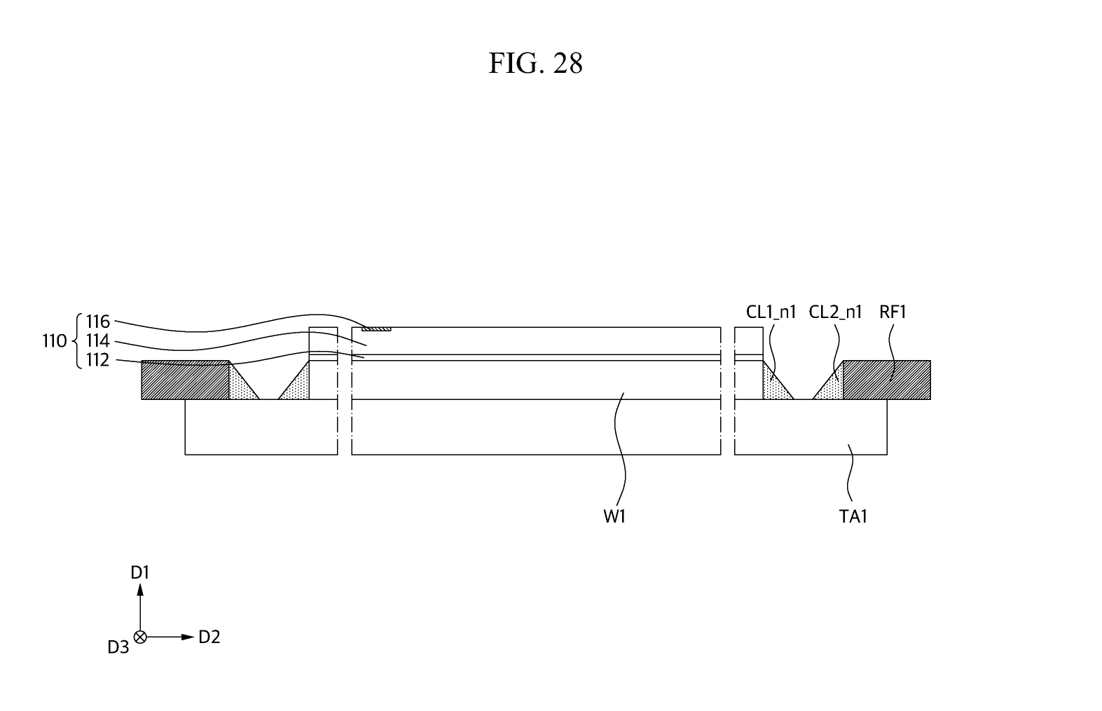

FIGS. 28-45 are cross-sectional views for illustrating a manufacturing order for describing a method of manufacturing a semiconductor package by using a method of manufacturing a semiconductor device according to an example embodiment of the present disclosure.

To the method of manufacturing the semiconductor device illustrated in FIGS. 28-45 a series of the methods of manufacturing the semiconductor device illustrated in FIGS. 1-18 may be applied. Therefore, descriptions which are already described with reference to FIGS. 1-18 will be omitted or simplified hereinafter for conciseness.

Firstly, a first wafer W1 may be attached to a first tape TA1. As illustrated in FIG. 1, a first ring frame RF1, which surrounds the first wafer W1 at the gap G, may also be attached to the first tape TA1. Further, a first coating layer CL1_n1 may be formed along an outer surface of the first wafer W1, and a second coating layer CL2_n1 may be formed along an outer surface of the ring frame RF.

According to an example embodiment, a first semiconductor die 110 may be formed on the first wafer W1. The first semiconductor die 110 may include a first adhesive layer 112, a first chip body 114 and a first connection pad 116. The first adhesive layer 112 may extend along a rear surface of the first chip body 114, and a side surface of the first adhesive layer 112 may be aligned with a side surface of the first chip body 114. The first adhesive layer 112 may be attached to the rear surface of the first chip body 114, to serve to allow the first semiconductor die 110 to be attached to another component and the like.

In the method of manufacturing of the example embodiment illustrated in FIG. 28, the rear surface of the first chip body 114 denotes a surface at which the first adhesive layer 112 is arranged, and a front surface of the first chip body 114 denotes a surface at which the first connection pad 116 is formed to serve as an electrical terminal.

According to an example embodiment, a semiconductor device may be formed on an active surface of the first chip body 114. The semiconductor device may include various kinds of individual devices. The plurality of individual devices may include various microelectronic devices, for instance, MOSFETs, such as complementary metal-oxide-semiconductor (CMOS) transistors, system LSI circuits, image sensors such as CISs and so on, MEMSs, active devices, and/or passive devices. In an example, the first semiconductor die 110 may be a memory semiconductor chip.

According to an example embodiment, the first adhesive layer 112 may include a non-conductive film (NCF), a non-conductive paste (NCP), an insulating polymer and/or an epoxy resin. Nevertheless, a material included in the first adhesive layer 112 is not limited to the listed materials.

According to an example embodiment, the first chip body 114 may include a semiconductor material such as silicon, germanium, silicon-germanium and the like, or a Ⅲ-Ⅴ compound semiconductor such as gallium phosphide (GaP), gallium arsenide (GaAs), gallium antimonide (GaSb) and the like. According to some example embodiments, the first chip body 114 may be a silicon-on-insulator (SOI) substrate or a germanium-on-insulator (GOI) substrate.

According to an example embodiment, the first connection pad 116 may be arranged at one side of the front surface of the first chip body 114. The first connection pad 116 may be exposed at the front surface of the first chip body 114. The first connection pad 116 may provide a terminal for the first semiconductor die 110 to be electrically connected to another component.

According to an example embodiment, the first connection pad 116 may include at least one metal selected from tungsten (W), aluminum (Al), or copper (Cu).

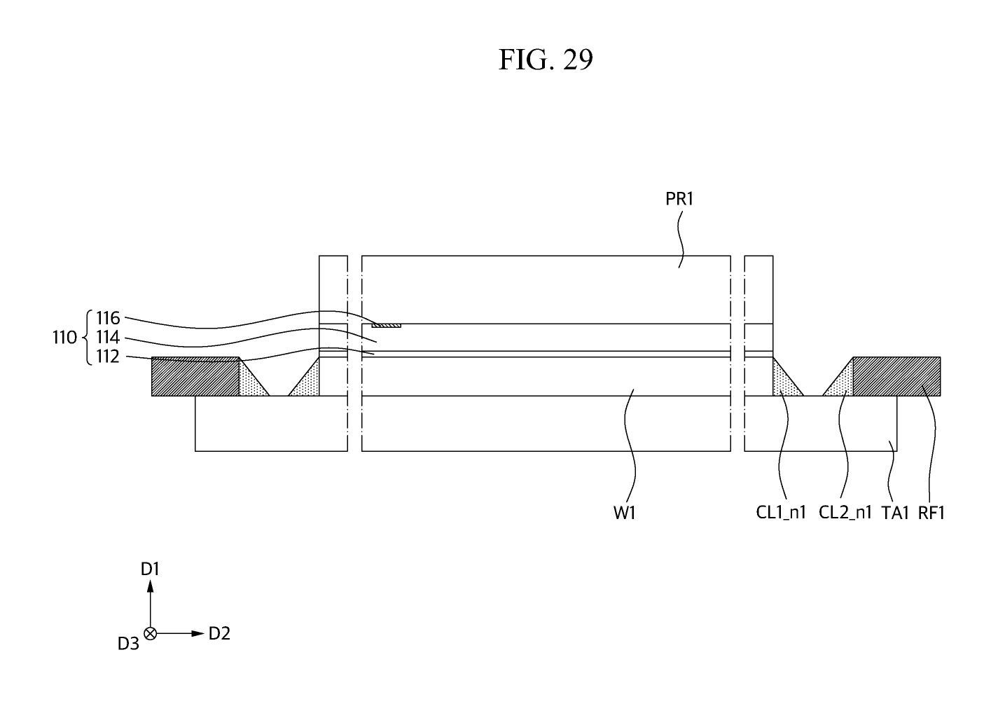

Referring to FIG. 29, a first photoresist layer PR1 may be formed on the front surface of the first chip body 114. The first photoresist layer PR1 may cover a surface of the first connection pad 116 exposed from the first chip body 114. The first photoresist layer PR1 may include a polymer binder, a photosensitizer, an organic solvent, or a combination thereof. According to an example embodiment, the first photoresist layer PR1 may have an identical configuration to that of the sacrificial film 11 illustrated in FIG. 14 and thus a repeated description thereof is omitted for conciseness.

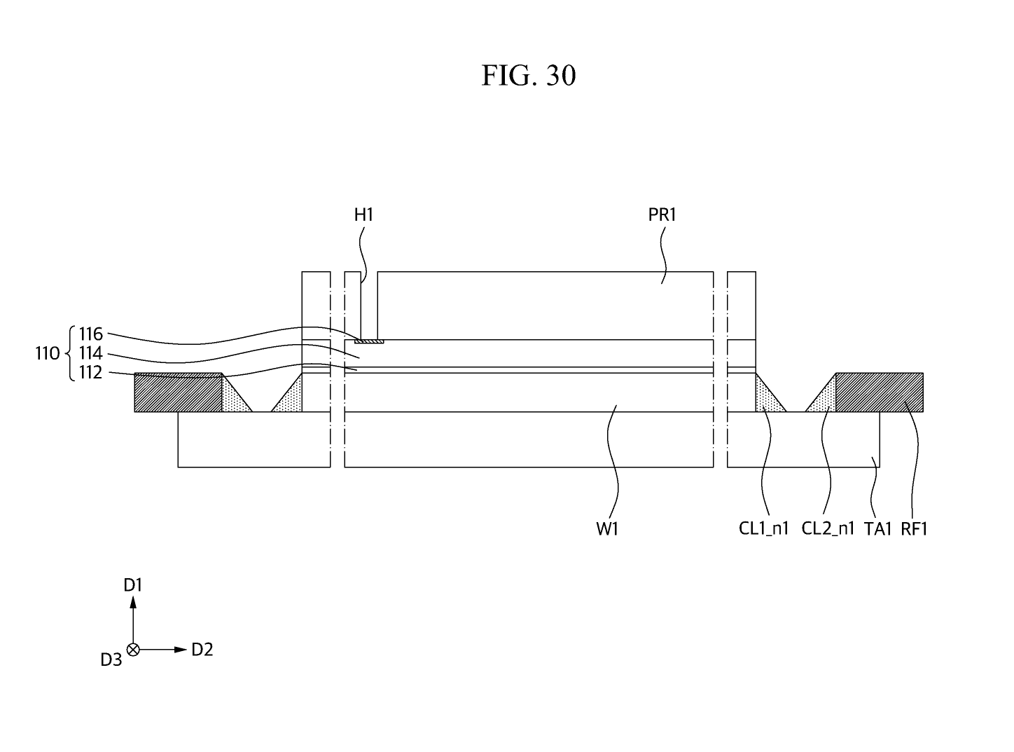

Referring to FIG. 30, a first hole H1 may be formed at the first photoresist layer PR1 to extend in the first direction D1. The first direction D1 may be a direction intersecting with the front surface of the first chip body 114. For instance, the first hole H1 may be formed by an etching process, but a process of forming the first hole H1 is not necessarily limited to the etching process.

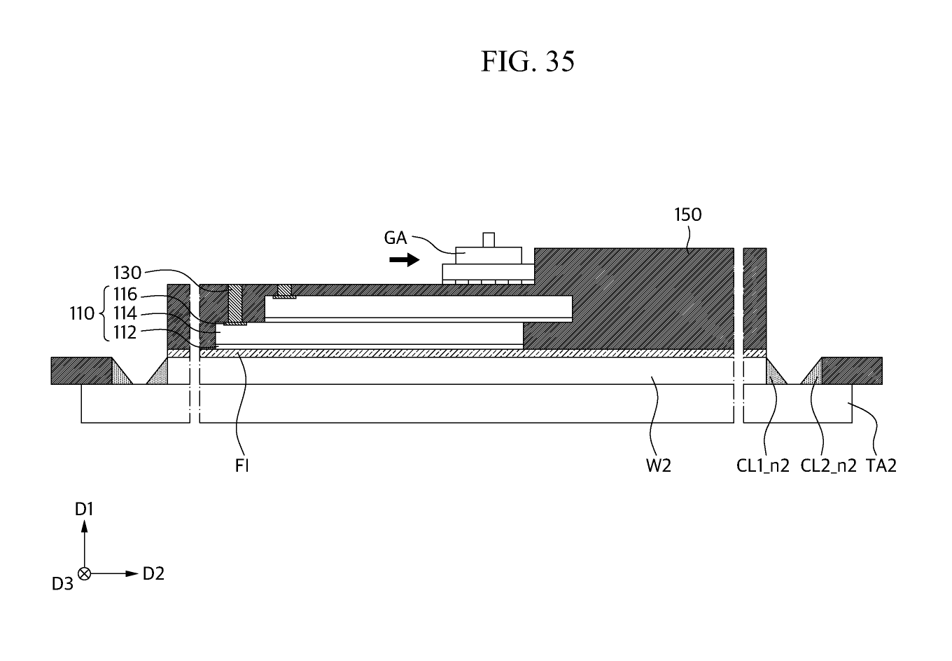

According to an example embodiment, the first hole H1 may be a hole overlapping the first connection pad 116 in the first direction D1. The first hole H1 may be formed to completely penetrate a portion of the first photoresist layer PR1. The first connection pad 116 may be exposed through the first hole H1 which is formed. According to an example embodiment, a width in a horizontal direction (the second direction D2 and/or the third direction D3) of the first hole H1 may be less than a width in a horizontal direction (the second direction D2 and/or the third direction D3) of the first connection pad 116. The second direction D2 may be defined as a direction being in parallel with the front surface of the first chip body 114, while being a direction in which the plurality of first semiconductor dies 110, which are stacked in a stepwise manner, are offset, as illustrated in FIG. 35 hereinafter. The third direction D3 may be a direction intersecting with the first direction D1 and the second direction D2. In an example embodiment, a width in a horizontal direction (the second direction D2 and/or the third direction D3) of the first hole H1 may be greater than a width in a horizontal direction (the second direction D2 and/or the third direction D3) of the first connection pad 116.

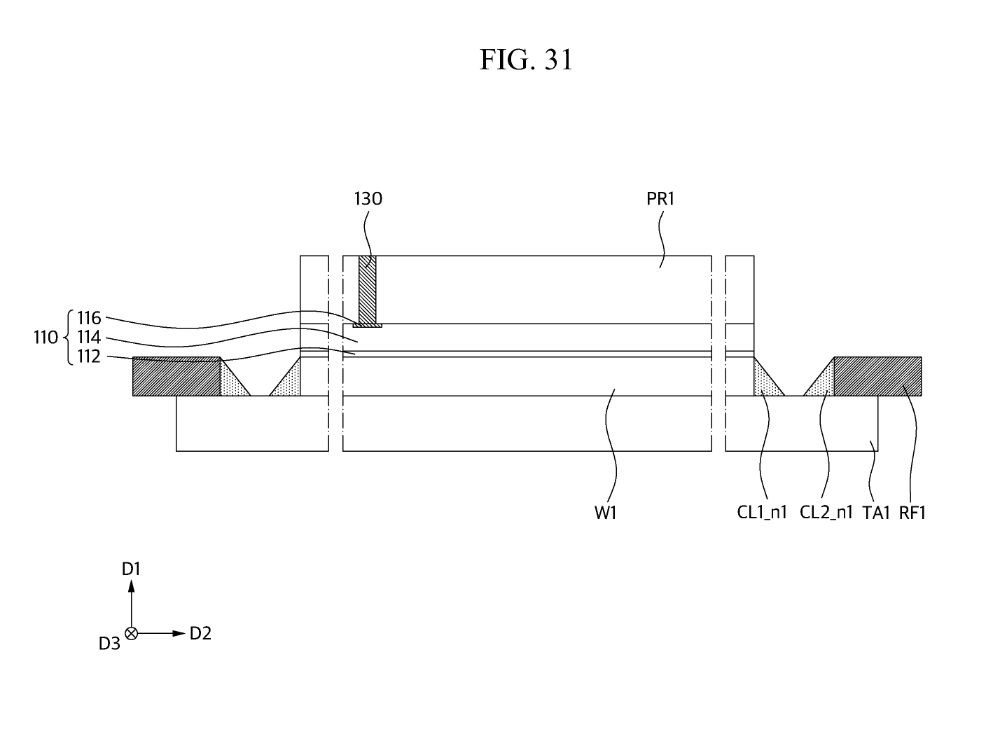

Referring to FIG. 31, a first conductive post 130 may be formed by filling a conductive material in the first hole H1. The first conductive post 130 may be connected to the first connection pad 116 to extend in the first direction D1.

According to an example embodiment, the first conductive post 130 may have a shape of a cylindrical post. Nevertheless, the shape of the first conductive post 130 is not limited thereto.

According to an example embodiment, the first conductive post 130 may include a conductive plug in a pillar shape and a conductive barrier film in a cylindrical shape enclosing a side wall of the conductive plug. The conductive plug may include at least one material selected from Cu, Cu alloys such as CuSn, CuMg, CuNi, CuZn, CuPd, CuAu, CuRe, CuW and the like, W, a W alloy, Ni, Ru and Co, and the conductive barrier film may include at least one material selected from Ti, TiN, Ta, TaN, Ru, Co, Mn, WN, Ni, and NiB.

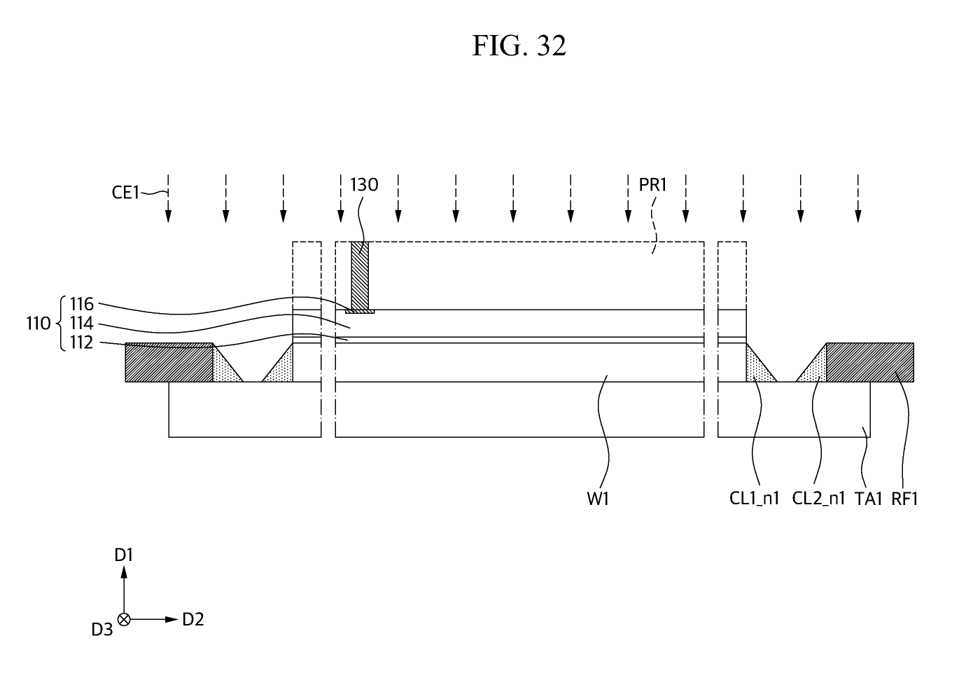

Referring to FIG. 32, the first photoresist layer PR1 (refer to FIG. 31) may be removed through a stripping process. In the stripping process, the first photoresist layer PR1 may be removed through the stripping solution CE1. The stripping process performed in FIG. 32 may be the stripping process described with reference to FIG. 15.

According to an example embodiment, as described with reference to FIGS. 14 and 15, because the first coating layer CL1_n1 is formed along an outer circumference of the first wafer W1, the stripping solution CE1 may not infiltrate into an interface between the first wafer W1 and the first tape TA1. Therefore, an adhesive force between the first wafer W1 and the first tape TA1 may be maintained during a stripping process.

As described with reference to FIG. 14 and FIG. 15, because the second coating layer CL2_n1 is formed along an inner circumference of the first ring frame RF1, the stripping solution CE1 may not infiltrate into an interface between the first ring frame RF1 and the first tape TA1. Therefore, an adhesive force between the first ring frame RF1 and the first tape TA1 may be maintained during a stripping process.

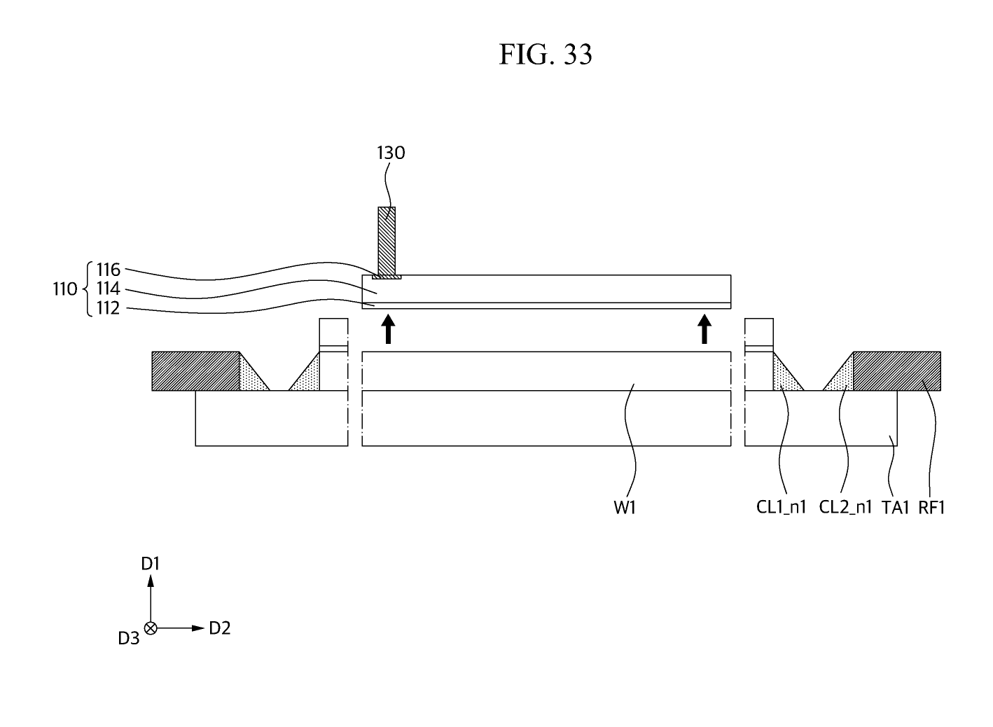

Referring to FIG. 33, the first semiconductor die 110, of which the stripping process, described with reference to FIG. 32, is completed, may be separated from the first wafer W1. Dicing may be performed with respect to the first wafer W1 in order to separate the first semiconductor die 110. After the dicing with respect to the first wafer W1, the first semiconductor die 110 which is located at a central area of the first wafer W1 may be picked up. Descriptions thereof are described with reference to FIGS. 19-23, and thus, duplicate descriptions will be omitted for conciseness.

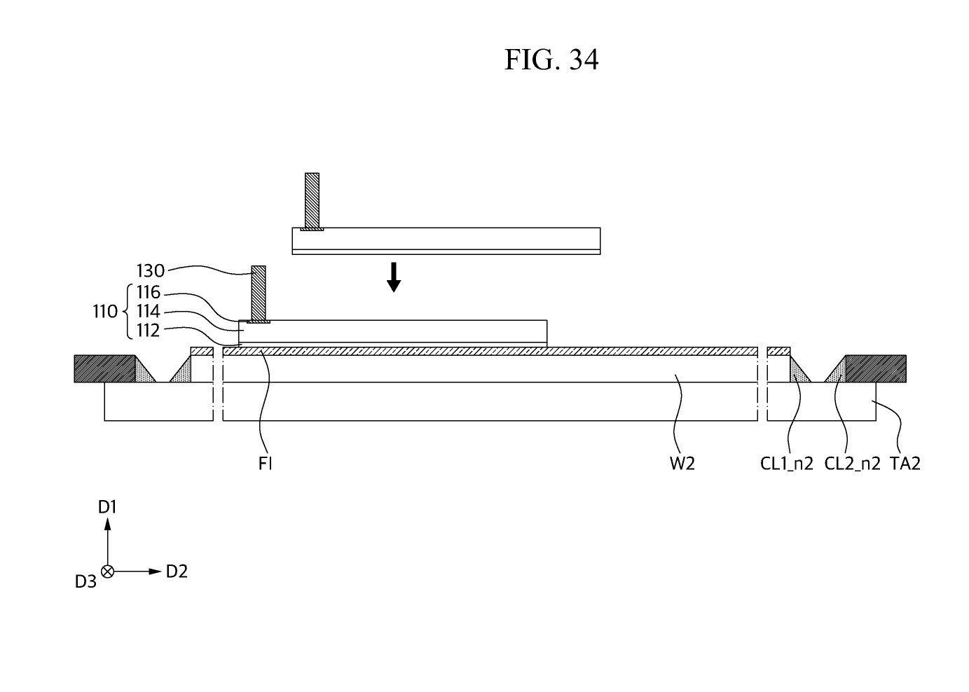

Referring to FIG. 34, the plurality of first semiconductor dies 110 may be stacked on a second wafer W2 attached to a second tape TA2. In an example embodiment, a film FI may be attached onto a main surface of the second wafer W2. A lowermost end of the first semiconductor die 110 may be attached to the film FI. The first adhesive layer 112 of the plurality of first semiconductor dies 110 may be aligned to face the film FI.

According to an example embodiment, the film FI may include an NCF, an NCP, an insulating polymer and/or an epoxy resin.

According to an example embodiment, in the same manner as the first tape TA1 and the first wafer W1 illustrated in FIG. 28, a second ring frame RF2 surrounding the second wafer W2 at a gap may also be attached to the second tape TA2. A first coating layer CL1_n2 may be formed between the second tape TA2 and the second wafer W2. A second coating layer CL2_n2 may be formed between the second tape TA2 and the second ring frame RF2.

According to an example embodiment, the plurality of first semiconductor dies 110 may be stacked in a stepwise manner in the first direction D1. Because the plurality of first semiconductor dies 110 are arranged to be offset with each other in the second direction D2, the first connection pad 116 of each of the first semiconductor dies 110 may not overlap another one of the first semiconductor dies 110. The first adhesive layer 112 of the first semiconductor die 110, which is stacked at the first semiconductor die 110 located at a lower end, may be attached to a front surface of the first chip body 114 located at a lower end.

Referring to FIG. 35, a first molding layer 150 may be formed on the second wafer W2 to cover the film FI. The first molding layer 150 may cover the film FI while surrounding the plurality of first semiconductor dies 110 and the plurality of first conductive posts 130.

According to an example embodiment, an upper end portion of the first molding layer 150 may be ground by a grinding apparatus GA afterwards. While the upper end portion of the first molding layer 150 is ground, an upper end portion of the first conductive post 130 may be removed along with the upper end portion of the first molding layer 150. Front surfaces of the plurality of first conductive posts 130 of which the upper end portion is removed may all be aligned. Further, the front surfaces of the plurality of first conductive posts 130 may be aligned with a front surface of the first molding layer 150.

“Being aligned” in the example embodiment illustrated in FIG. 35 denotes that components are arranged to constitute a practically identical flat surface with each other within an allowable error range. Here, “identical flat surface” may include a state in which a reference surface of individual components constitutes a consequentially continuous flat surface through a dicing or polishing process by allowing for a step which may be generated during a process.

According to an example embodiment, the first molding layer 150 may include a thermo-curable resin such as an epoxy resin. Nevertheless, a material of the first molding layer 150 is not limited to the epoxy resin. The first molding layer 150 may include a plurality of fillers constituted with silica or a silica compound.

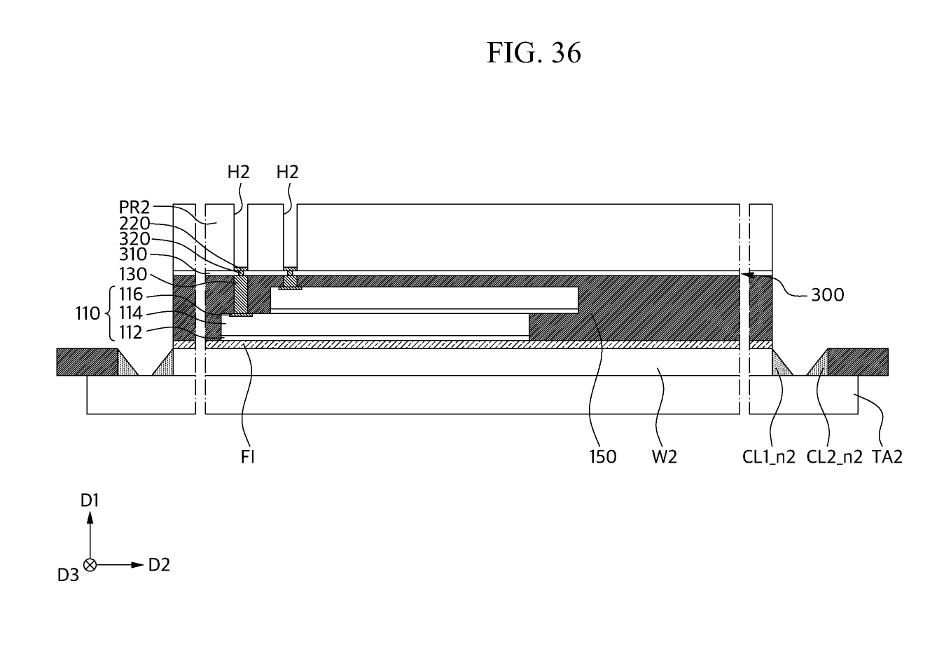

Referring to FIG. 36, an intermediate redistribution structure 300 may be formed on the front surface of the first molding layer 150. Firstly, an intermediate redistribution insulation layer 310 may be formed on the front surface of the first molding layer 150. Next, an etching process is progressed with respect to the intermediate redistribution insulation layer 310, before a conductive material is filled in a trench formed through the etching process to form an intermediate redistribution via 320. After the intermediate redistribution via 320 is formed, a connection pad 220 may be formed on the intermediate redistribution via 320. The intermediate redistribution via 320 may be formed to be connected to the first conductive post 130. The connection pad 220 may be formed to be connected to the intermediate redistribution via 320. The intermediate redistribution via 320 and the connection pad 220 may be provided in plural. The plurality of connection pads 220 may be respectively connected in response to the intermediate redistribution via 320.

According to an example embodiment, the intermediate redistribution insulation layer 310 may include silicon oxide, silicon nitride, silicon oxynitride, an insulation material having a dielectric constant lower than that of silicon oxide, or a combination thereof. The intermediate redistribution via 320 and the connection pad 220 may include at least one metal selected from tungsten (W), aluminum (Al), or copper (Cu).

Thereafter, a second photoresist layer PR2 may be formed on a front surface of the intermediate redistribution structure 300. A second hole H2 may be formed at the second photoresist layer PR2 to overlap the connection pad 220.

According to an example embodiment, the second hole H2 may be a hole overlapping the connection pad 220 in the first direction D1. The second hole H2 may be formed to completely penetrate a portion of the second photoresist layer PR2. The connection pad 220 may be exposed through the second hole H2 which is formed.

According to an example embodiment, the second photoresist layer PR2 may have an identical configuration to that of the first photoresist layer PR1 illustrated in FIG. 29. Therefore, duplicate descriptions will be omitted hereinafter for conciseness.

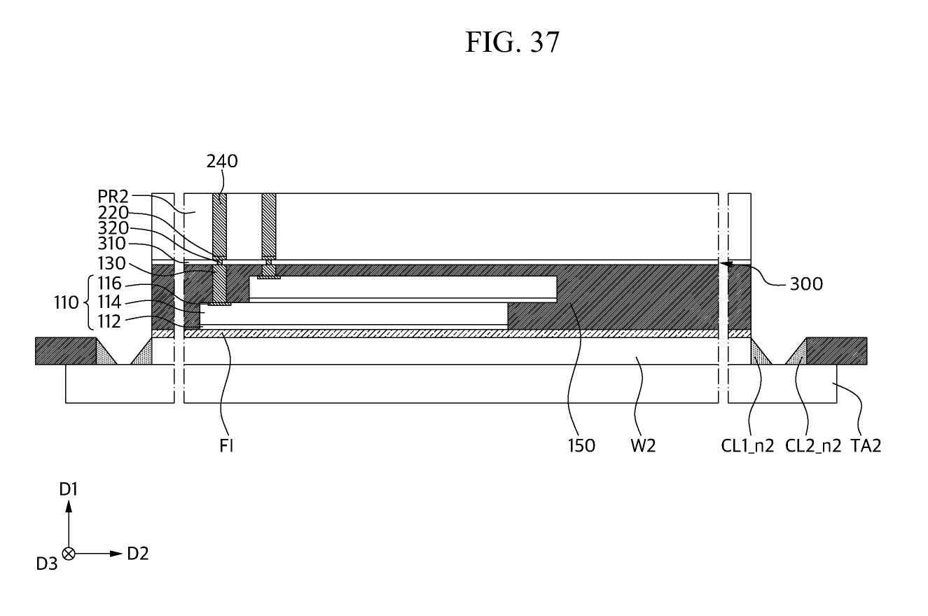

Referring to FIG. 37, a second conductive post 240 may be formed by filling a conductive material in the second hole H2. The second conductive post 240 may be connected to the connection pad 220 to extend in the first direction D1.

According to an example embodiment, the second conductive post 240 may have a shape of a cylindrical post. Nevertheless, the shape of the second conductive post 240 is not limited thereto.

According to an example embodiment, a material included by the second conductive post 240 may be similar to a material included in the first conductive post 130, and thus, specific descriptions thereof will be omitted hereinafter for conciseness.

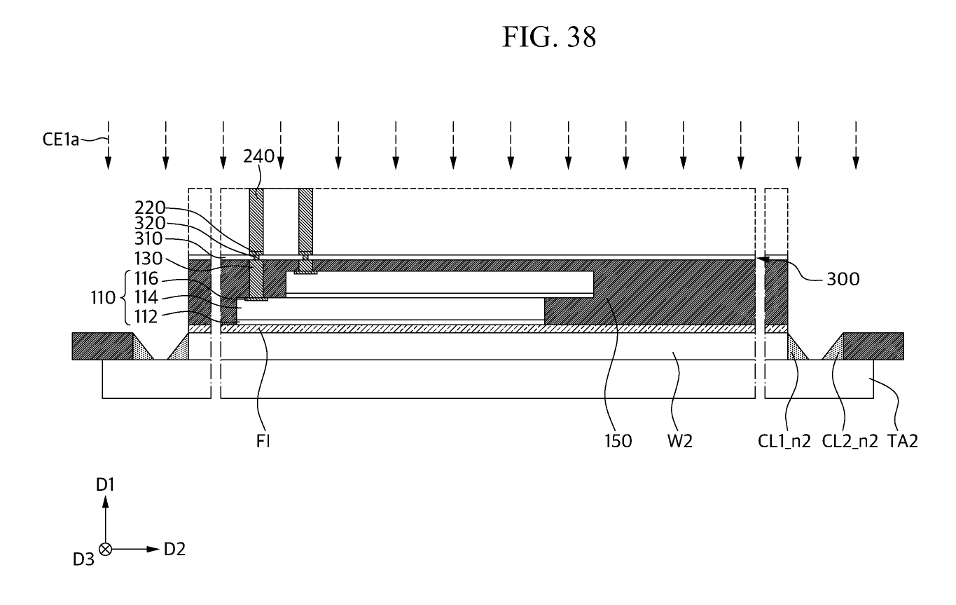

Referring to FIG. 38, the second photoresist layer PR2 (refer to FIG. 37) may be removed through a stripping process. In the stripping process, the second photoresist layer PR2 may be removed through a stripping solution CE1a. The stripping process performed in FIG. 38 may be the stripping process described with reference to FIG. 15.

According to an example embodiment, as described with reference to FIGS. 14 and 15, because the first coating layer CL1_n2 is formed along an outer circumference of the second wafer W2, the stripping solution CE1a may not infiltrate into an interface between the second wafer W2 and the second tape TA2. Therefore, an adhesive force between the second wafer W2 and the second tape TA2 may be maintained during a stripping process.

As described with reference to FIGS. 14 and 15, because the second coating layer CL2_n2 is formed along an inner circumference of the second ring frame RF2, the stripping solution CE1a may not infiltrate into an interface between the second ring frame RF2 and the second tape TA2. Therefore, an adhesive force between the second ring frame RF2 and the second tape TA2 may be maintained during a stripping process.

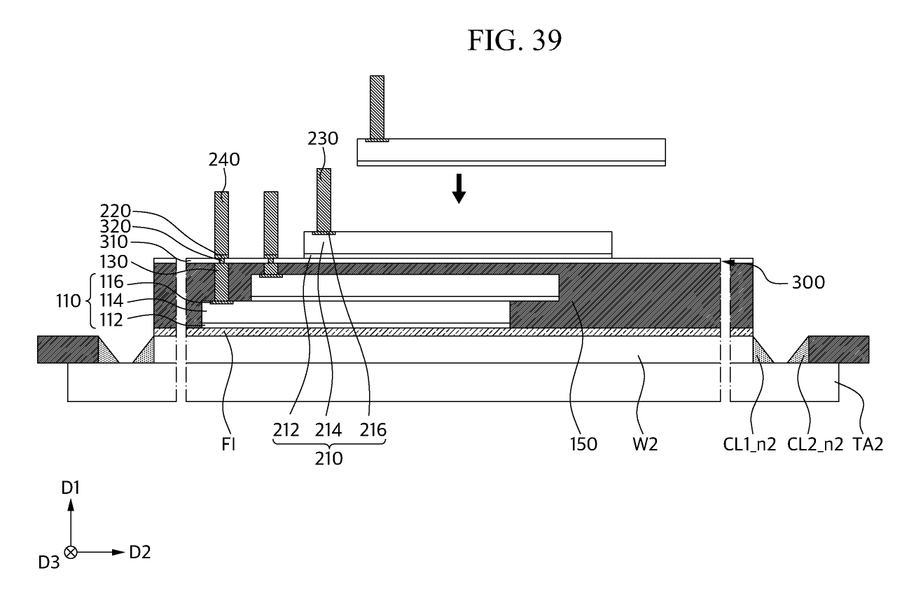

Referring to FIG. 39, a plurality of second semiconductor dies 210 may be stacked in a stepwise manner on the intermediate redistribution structure 300 in the first direction D1. The second semiconductor die 210 may include a second adhesive layer 212, a second chip body 214 and a second connection pad 216. The second adhesive layer 212 may include a material which may achieve bonding in a relationship to the intermediate redistribution insulation layer 310 or the second chip body 214.

According to an example embodiment, the second connection pad 216 and the second adhesive layer 212 may be practically identical to the first connection pad 116 and the first adhesive layer 112. The second chip body 214 may be practically identical to the first chip body 114 according to an example embodiment. In an example embodiment, both of the second chip body 214 and the first chip body 114 may include a memory device. In some example embodiments, the second chip body 214 may be a body of a chip of a different type from that of the first chip body 114. For instance, one of the second chip body 214 and the first chip body 114 may be a body of a memory chip, and the other one may be a body of a logic chip. Among descriptions of the second semiconductor die 210, the descriptions already mentioned with reference to the first semiconductor die 110 will be omitted hereinafter for conciseness.

According to an example embodiment, because the plurality of second semiconductor dies 210 are arranged to be offset with each other in the second direction D2, the second connection pad 216 of each semiconductor die may not overlap another semiconductor die. The second adhesive layer 212 of the second semiconductor die 210, which is stacked on a lower end of the second semiconductor die 210, may be attached to a front surface at a lower end of the second chip body 214.

According to an example embodiment, a second conductive post 230 may be attached to the second connection pad 216 of each second semiconductor die 210.

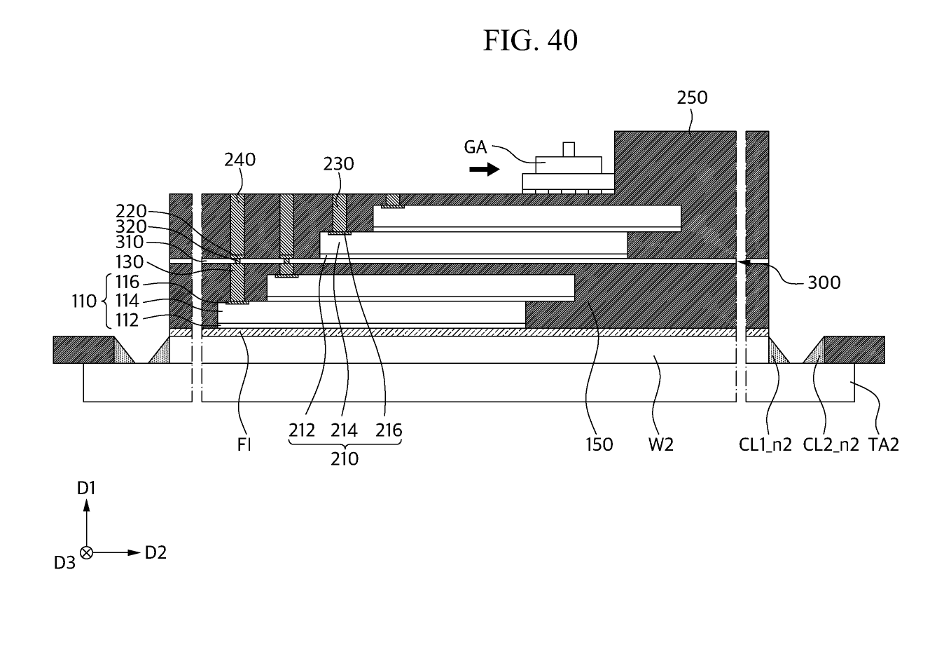

Referring to FIG. 40, a second molding layer 250 may be formed on the intermediate redistribution structure 300. The second molding layer 250 may cover the intermediate redistribution structure 300 while surrounding the plurality of second semiconductor dies 210 and the plurality of second conductive posts 230.

According to an example embodiment, an upper end portion of the second molding layer 250 may be ground by the grinding apparatus GA afterwards. While the upper end portion of the second molding layer 250 is ground, an upper end portion of the second conductive post 230 may be removed along with the upper end portion of the second molding layer 250. Front surfaces of the plurality of second conductive posts 230 of which the upper end portion is removed may be aligned. Further, the front surfaces of the plurality of second conductive posts 230 may be aligned with a front surface of the second molding layer 250.

According to an example embodiment, the second molding layer 250 may have a practically identical configuration to that of the first molding layer 150. In some example embodiments, in order to prevent warpage caused by a difference of thermal expansion of the first molding layer 150 and the second molding layer 250, the second molding layer 250 may have a material and a configuration different from those of the first molding layer 150.

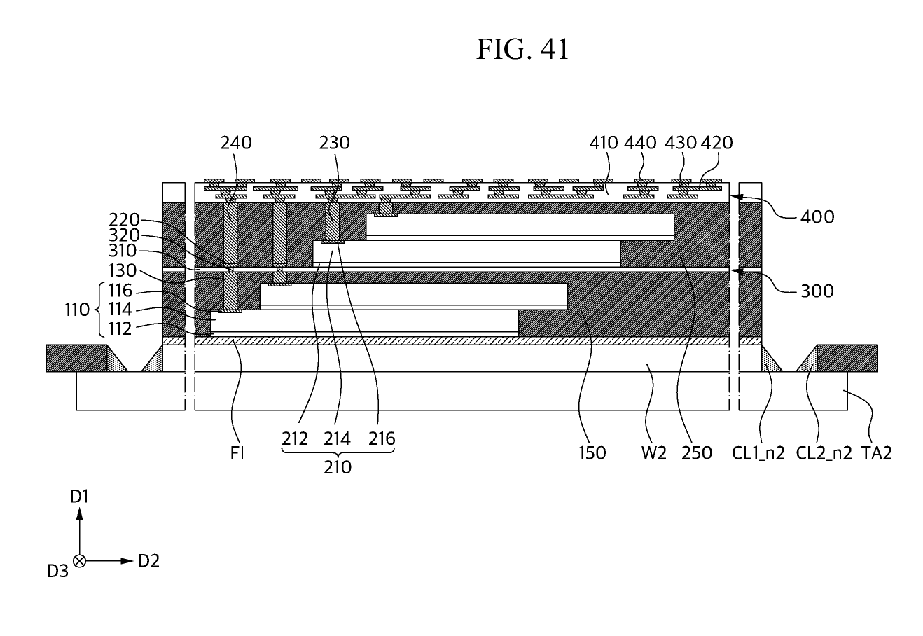

Referring to FIG. 41, a redistribution structure 400 may be formed on the front surface of the second molding layer 250. Firstly, a redistribution insulation layer 410 may be formed on the front surface of the second molding layer 250. Afterwards, an etching process may be performed with respect to the redistribution insulation layer 410, before a conductive material may be filled in a trench formed through the etching process to form a redistribution via 430. After the redistribution via 430 is formed, a redistribution pattern 420 may be formed on the redistribution via 430. The redistribution via 430 at a lowermost end may be formed to be connected to the second conductive post 230. Forming the redistribution insulation layer 410, forming the redistribution via 430, and forming the redistribution pattern 420 may be repeated. After the repeated processes, a redistribution pad 440 may be formed on the redistribution via 430 at an uppermost end. Lastly, with formation of the redistribution pad 440, the redistribution structure 400 may be completed.

According to an example embodiment, an etching process may be performed in forming the redistribution structure 400. For instance, the etching process may be performed with respect to the redistribution insulation layer 410 to form the redistribution via 430. Further, although not illustrated in detail, depending on an example embodiment, a seed layer may be formed to surround at least a portion of the redistribution via 430 and the redistribution pattern 420, wherein the etching process may be progressed to form the seed layer as illustrated in FIGS. 17 and 18.

According to an example embodiment, as described with reference to FIGS. 17 and 18, because the first coating layer CL1_n2 is formed along the outer circumference of the second wafer W2, the etching fluid CE2 (refer to FIG. 18) which is used in the etching process may not infiltrate into the interface between the second wafer W2 and the second tape TA2. Therefore, an adhesive force between the second wafer W2 and the second tape TA2 may be maintained during the etching process.

As described with reference to FIGS. 17 and 18, because the second coating layer CL2_n2 is formed along the inner circumference of the second ring frame RF2, the etching fluid CE2 may not infiltrate into the interface between the second ring frame RF2 and the second tape TA2. Therefore, an adhesive force between the second ring frame RF2 and the second tape TA2 may be maintained during the etching process.

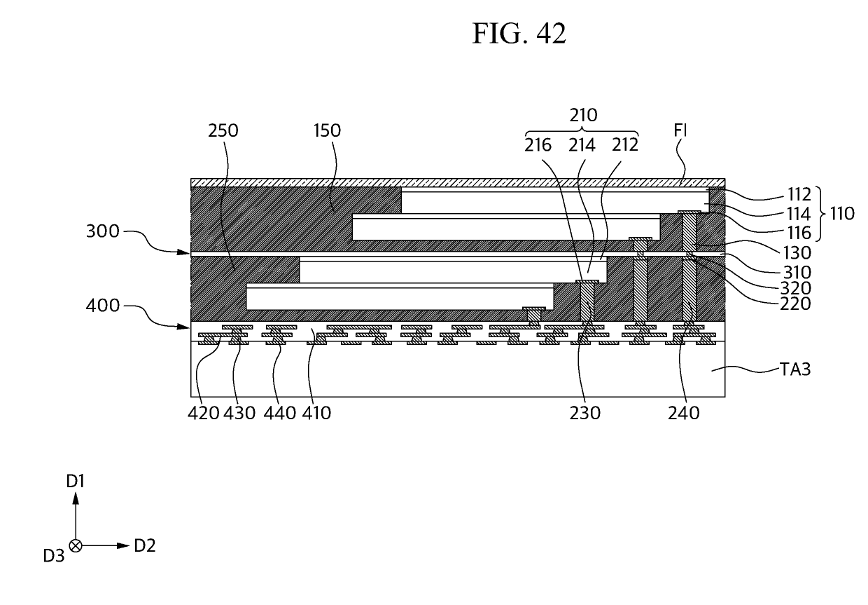

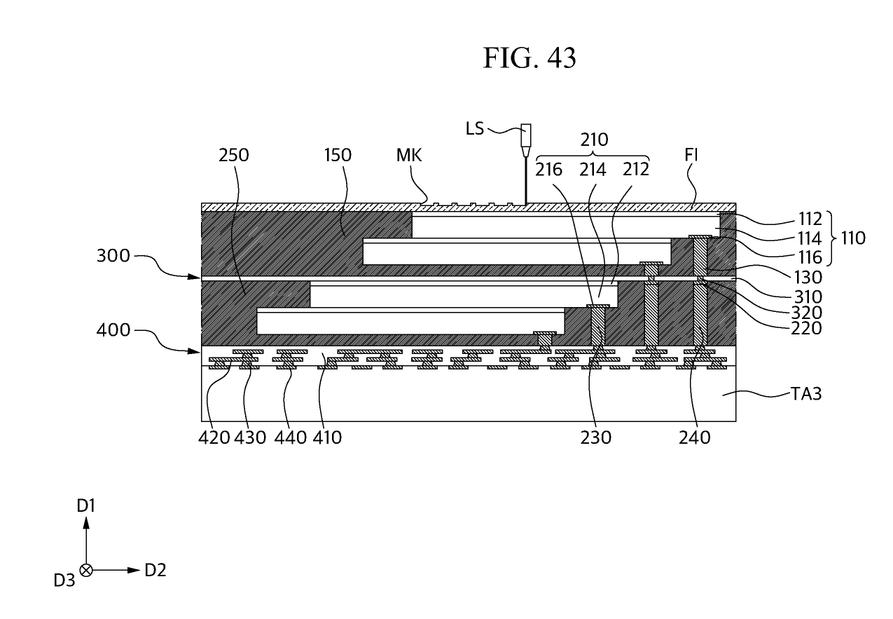

Referring to FIGS. 42 and 43, a result up to FIG. 41 may be turned over before the redistribution structure 400 is attached to a third tape TA3.

According to an example embodiment, the redistribution structure 400 may be aligned to face the third tape TA3. The redistribution structure 400 may be attached to the third tape TA3. The redistribution pad 440 exposed at the redistribution structure 400 from the redistribution insulation layer 410 may be attached to the third tape TA3.

According to an example embodiment, after the redistribution structure 400 is attached to the third tape TA3, the second wafer W2 may be attached to and detached from the film FI.

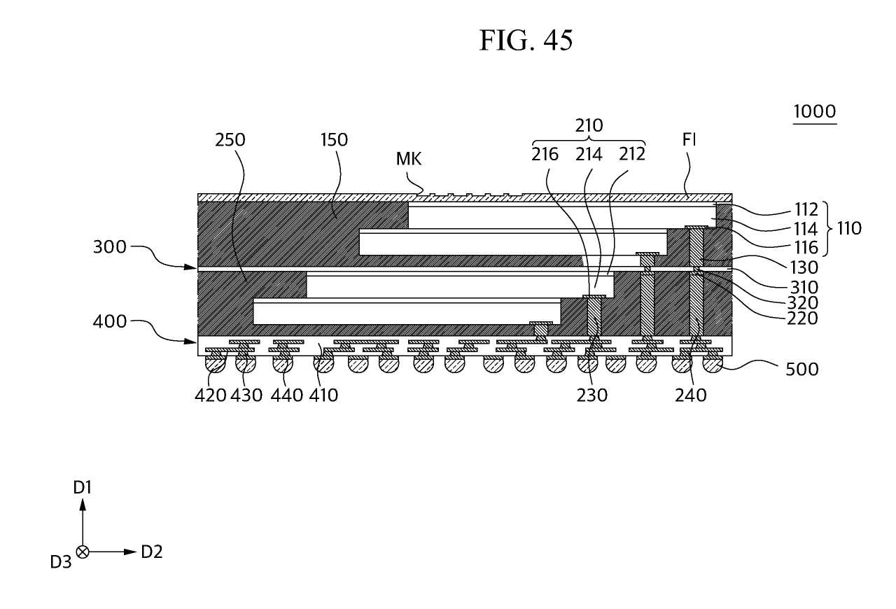

Afterwards, a marking pattern MK may be formed at the film FI by using a laser LS. The marking pattern MK may indicate identification information of a semiconductor package 1000 (refer to FIG. 45). Here, the identification information may include various pieces of information having traceability of the semiconductor package 1000, for instance, a process number, a manufacturing company, a manufacturing date, a product name, a product type and/or a combination thereof. The marking pattern MK may include not only a sign, a number, and a letter but also a two-dimensional barcode which is a more indirect identification manner. For instance, the two-dimensional barcode may be implemented in various kinds such as a data matrix, a QR code and the like.

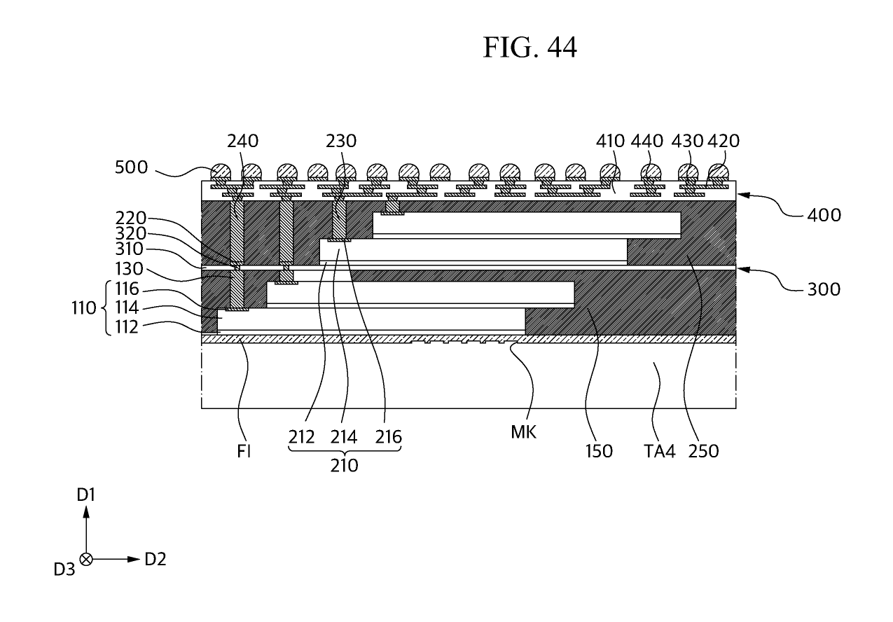

Referring to FIGS. 44 and 45, a result up to FIG. 43 may be turned over before the film FI is attached to a fourth tape TA4.

According to an example embodiment, the result up to FIG. 43 may be aligned for the film FI to face the second tape TA2. And the first tape TA1 may be removed from the redistribution structure 400. As the first tape TA1 is removed, the redistribution pad 440 of the redistribution structure 400 may be exposed to the outside.

Afterwards, an external connecting terminal 500 may be attached to the redistribution pad 440. When the fourth tape TA4 is removed from the film FI after the external connecting terminal 500 is attached, the semiconductor package 1000 according to an example embodiment may be completed.

A method of manufacturing a semiconductor device according to an example embodiment of the present disclosure may include forming a coating layer (e.g., the first coating layer CL1 and the second coating layer CL2, refer to FIG. 4) along a circumference of the wafer W (refer to FIG. 2) after the wafer W is attached to the tape TA (refer to FIG. 2) along with the ring frame RF (refer to FIG. 2). The coating layer serves to perform sealing in order to prevent a portion of the outer surface W_s (refer to FIG. 5) of the wafer W and an upper surface of the tape TA from being exposed. Because the first coating layer CL1 is formed along a circumference of the wafer W, a chemical material used in a process may not infiltrate into an interface between the wafer W and the tape TA. Because a chemical material does not infiltrate into the interface between the wafer W and the tape TA by the second coating layer CL2, an adhesive force between the wafer W and the tape TA may be maintained during a process.

According to some example embodiments, a method of manufacturing a semiconductor device may include attaching a wafer to a tape, and a ring frame to the tape, the ring frame surrounding an outer edge of the wafer with a gap between the wafer and the ring frame, forming a first coating layer in the gap to contact the wafer in the gap, and a second coating layer in the gap to contact the ring frame in the gap, forming, on the wafer, a semiconductor die including an adhesive layer contacting a surface of the wafer, a chip body having a rear surface contacting the adhesive layer, and a connection pad that is exposed on a front surface of the chip body, forming a photoresist layer on a rear surface of the chip body, forming a hole in the photoresist layer to expose the connection pad, forming a conductive post by filling a conductive material in the hole, and removing the photoresist layer through a stripping process.

In an example embodiment, the first coating layer may cover a portion of an outer surface of the wafer that faces the ring frame and may cover an upper surface of the tape that intersects with the outer surface of the wafer in the gap.

In an example embodiment, the method may further include, after removing the photoresist layer, dicing the wafer and picking up a semiconductor die at which the conductive post is formed on a rear surface.

In an example embodiment, the first coating layer and the second coating layer may be spaced apart from each other in a radial direction from a center of the wafer on a plane parallel with a main surface of the wafer.

In an example embodiment, the conductive post may be formed to contact the connection pad.

In an example embodiment, the photoresist layer may be removed by using a fluid on the wafer, the fluid including tetramethylammonium hydroxide (TMAH), DMSO, or a combination thereof.

Various example embodiments have been described above with reference to the drawings. Although the various example embodiments have been described using specific terminology in this specification, the specific terminology is used only for the purpose of describing the technical spirit of the present disclosure and is not used to limit the scope of the present disclosure as defined in the appended claims. Therefore, those of ordinary skill in the art will understand that various modifications and other equivalent example embodiments are possible therefrom and are to be included within the scope of the appended claims.

What is claimed is:

1. A method of manufacturing a semiconductor device, the method comprising:
attaching a wafer to a tape, and a ring frame to the tape, the ring frame surrounding an outer edge of the wafer with a gap between the wafer and the ring frame;
forming a first coating layer in the gap to contact with the wafer, and a second coating layer in the gap to contact with the ring frame;
curing the first coating layer and the second coating layer;
forming a sacrificial film on the wafer to contact with the first coating layer that has been cured; and
removing the sacrificial film.

2. The method of claim 1, wherein the removing comprises performing a stripping process.

3. The method of claim 1, wherein each of the first coating layer and the second coating layer comprises an epoxy resin, a urethane resin, or a combination thereof.

4. The method of claim 1, wherein the removing comprises applying a fluid to the wafer, the fluid including tetramethylammonium hydroxide (TMAH), dimethyl sulfoxide (DMSO), or a combination thereof.

5. The method of claim 1, wherein the first coating layer is formed to cover a portion of an outer surface of the wafer that faces the ring frame and to cover a portion of an upper surface of the tape that intersects with the outer surface of the wafer in the gap.

6. The method of claim 1, wherein the second coating layer is formed to cover a portion of an inner surface of the ring frame that faces the wafer and to cover a portion of an upper surface of the tape that intersects with the inner surface of the ring frame in the gap.

7. The method of claim 1, wherein forming the first coating layer and the second coating layer comprises discharging a coating material into the gap with a dispenser.

8. The method of manufacturing the semiconductor device of claim 1, wherein the forming the first coating layer and the second coating layer comprises spraying a coating material into the gap with an inkjet printing device.

9. The method of manufacturing the semiconductor device of claim 1, wherein the first coating layer is formed to have an inclined side surface that faces the second coating layer, and the second coating layer is formed to have an inclined side surface that faces the first coating layer.

10. The method of claim 1, wherein the first coating layer is formed to have an outer surface that concavely bends towards the wafer, and the second coating layer is formed to have an outer surface that concavely bends towards the ring frame.

11. The method of claim 1, wherein the first coating layer is formed to have an outer surface that convexly bends towards the ring frame, and the second coating layer is formed to have an outer surface that convexly bends towards the wafer.

12. The method of claim 1, wherein the first coating layer and the second coating layer are formed on a plane that is parallel with a surface of the wafer and are formed to be spaced apart from each other in a radial direction from a center of the wafer.

13. A method of manufacturing a semiconductor device, the method comprising:
attaching a wafer to a tape, and a ring frame to the tape, the ring frame surrounding an outer edge of the wafer with a gap between the wafer and the ring frame;
forming a coating layer in the gap to contact an outer surface of the wafer in the gap;
curing the coating layer;
dicing the wafer into a plurality of dies, the wafer being in contact with the coating layer that has been cured; and
picking up a first die among the plurality of dies that is in a central area of the wafer with respect to a plane parallel with a surface of the wafer.

14. The method of claim 13, wherein, in picking up the first die, a second die among the plurality of dies that is at an edge area of the wafer remains in contact with the coating layer.

15. The method of claim 13, wherein the first die is not in contact with the coating layer.

16. The method of claim 13, wherein the curing comprises performing a UV curing process.

17. The method of claim 13, wherein the curing comprises performing a thermal curing process.

18. The method of claim 13, wherein the coating layer is formed in the gap to contact an inner surface of the ring frame that faces the wafer in the gap.

19. A method of manufacturing a semiconductor device, the method comprising:
attaching a wafer to a tape, and a ring frame to the tape, the ring frame surrounding an outer edge of the wafer with a gap between the wafer and the ring frame;
forming, with a dispenser that discharges a coating material including an epoxy resin, a first coating layer in the gap to cover a portion of an outer surface of the wafer that faces the ring frame and to cover a portion of an upper surface of the tape in the gap, and a second coating layer in the gap to cover a portion of an inner surface of the ring frame that faces the wafer and to cover a portion of the upper surface of the tape;
curing the first coating layer and the second coating layer using an UV curing process;
forming a photoresist film on the wafer, the portion of the outer surface of which is covered by the first coating layer that has been cured;
removing the photoresist film through a stripping process by using a fluid including dimethyl sulfoxide;
dicing the wafer from which the photoresist film has been removed into a plurality of dies; and
picking up a first die in a central area of the wafer that is not in contact with the first coating layer among the plurality of dies on a plane parallel with a surface of the wafer.

20. The method of claim 19, wherein in picking up the first die, a second die at an edge area of the wafer among the plurality of dies remains in contact with the first coating layer.
